(19) United States
(12) Patent Application Publication
(10) Pub. No.: US 2024/0218154 A1
(43) Pub. Date: Jul. 4, 2024

(54) OLEFIN-BASED POLYMER AND PEROXIDE COMPOSITIONS WITH EXCELLENT CURE RESPONSE

(71) Applicant: Dow Global Technologies LLC, Midland, MI (US)

(72) Inventors: Yabin Sun, Shanghai (CN); Gaoxiang Wu, Pearland, TX (US); Jeffrey C. Munro, Bellaire, TX (US); Colin Li Pi Shan, Pearland, TX (US); Brian M. Habersberger, Houston, TX (US); Thomas Wesley Karjala, Jr., Lake Jackson, TX (US); Johnathan E. DeLorbe, Manvel, TX (US)

(21) Appl. No.: 18/555,698

(22) PCT Filed: Jun. 30, 2021
(86) PCT No.: PCT/CN2021/103386

§ 371 Date: Oct. 16, 2023

(51) Int. Cl. C08K 5/14; C08K 5/00

(52) U.S. Cl. CPC C08K 5/14; C08K 5/0025

(57) ABSTRACT

Provided is a process to form a crosslinked composition. the process comprising applying heat. and optionally radiation. to a composition that comprises at least the following components a) and b): a) an olefin-based polymer that comprises a total unsaturation ≥ 0.20/1000 C: b) at least one peroxide selected from at least one of the following: i) a peroxide comprising at least one peroxy group comprising an oxyl radical unit of Radical I, ii) a peroxide comprising at least one peroxy group comprising an oxyl radical unit of Radical II, iii) a peroxide comprising at least one peroxy group comprising an oxyl radical unit of Radical III, iv) a peroxide comprising at least one peroxy group comprising an oxyl radical unit of Radical IV, or v) any combination of i) through iv); and wherein Radical I. Radical II. Radical III or Radical IV are each described herein.

### BACKGROUND OF THE INVENTION

The global photovoltaic market is growing very rapidly. The growth is driven by the increased efficiency and reduced cost of PV power generation versus traditional grid power sources, and government incentives for increased PV power sources. The PV encapsulation film is an important component of a PV module. Currently, films formed from ethylene vinyl acetate (EVA) are widely used as encapsulating materials for solar cells, due to the excellent transparency and curing response of EVA. EVA typically cures at a faster rate than conventional nonpolar olefin-based polymers. However, more recent, high efficiency PERC (Passivated Emitter and Rear Cell) bifacial modules exhibit high PID (potential induced degradation) risk, when using traditional EVA as the encapsulant film. Such olefin-based polymer compositions offer improved anti-PID performance, however, typically have a reduced peroxide curing response, as compared to EVA. Moving die rheometer (MDR) is used to characterize the curing response, and generates a MH (the maximum torque exerted) value and a T90 value (the time to achieve 90% of the (MH-ML), where ML is the minimum torque exerted).

In order to reduce the time for cure (lower the T90) of an olefin-based polymer, alternative peroxides with increased decomposing rates have been used. Such peroxides improve the curing rate, as indicated by a decrease in the T90 value, but also decrease the degree of cure, as indicated by a decrease in the MH value. There is a need for new olefin-based polymer compositions that provide an improved cure rate, while maintaining or increasing the degree of cure in the composition.

European Application EP2958151A1 discloses an encapsulant resin composition containing an ethylene/alpha-olefin (α-olefin) with a density of 0.860-0.920 g/cm³, an MFR of 0.1-100 g/10 min, and which meets the relationship N*V≥10, where N is the branch number derived from the comonomer, and V is the total number of vinyl and vinylidene, both per 1000 Carbons. Examples of organic peroxides include t-butylperoxyisopropyl carbonate; t-butyl peroxy-2-ethylhexyl carbonate; t-butylperoxyacetate; t-butylperoxybenzoate; dicumyl peroxide: 2,5-dimethyl-2,5-di(t-butylperoxy)hexane; di-t-butyl peroxide; 2,5-dimethyl-2,5-di-(t-butyl-peroxy)hexyne-3; 1,1-di-(t-butylperoxy)-3,3,5-trimethyl-cyclohexane; 1, 1-di-(t-butylperoxy)-cyclohexane; methyl ethyl ketone peroxide; 2,5-dimethyl-hexyl-2,5-diperoxybenzoate; t-butyl hydroperoxide; p-menthane hydroperoxide; benzoyl peroxide; p-chlorobenzoyl peroxide; t-butylperoxyisobutyrate; hydroxyheptyl peroxide; and dicyclohexanone peroxide (see paragraph [0058]). See also JP2012009688A (machine translation), where the total amount of vinyl, vinylidene, cis-vinylene, trans-vinylene, trisubstituted-vinylene in the ethylene/α-olefin copolymer is 0.22 (per 1000 C) or more.

International Publication WO2020/135680A1 discloses a curable composition for an encapsulant film; the curable composition comprising a telechelic polyolefin of the formula A¹L¹L²A² or an unsaturated polyolefin of the formula A¹L¹, and a curing component comprising a cross-linking agent, a coagent and a silane coupling agent. The crosslinking agent may include one or more organic peroxides including, but not limited to, alkyl peroxides, aryl peroxides, peroxyesters, peroxycarbonates, diacylperoxides, peroxyketals, cyclic peroxides, dialkyl peroxides, peroxy esters, peroxy dicarbonates, or combinations thereof. Examples of peroxides include di-tertbutyl peroxide; dicumyl peroxide; di-(3,3,5-trimethyl hexanoyl)peroxide; t-butyl peroxypivalate; t-butyl peroxyneodecanoate; di-(sec-butyl)peroxydicarbonate; t-amyl peroxyneodecanoate; 1,1-di-t-butyl peroxy-3,3,5-trimethylcyclohexane; t-butyl-cumyl peroxide; 2,5-dimethyl-2,5-di(tertiary-butylperoxyl)-hexane; 1,3-bis(tertiary-butyl-peroxyl-isopropyl)benzene; or a combination thereof. Exemplary crosslinking agents are dicumyl peroxide, commercially available under the tradename LUPEROX from Arkema or the tradename TRIGONOX from Akzo Nobel, and VAROX DBPH-50 from Vanderbilt Chemicals. See paragraph [0241]. See also WO2020/135708A1, WO2020/140058, WO2020/140061 and WO2020/140067.

European Application EP2637217A1 discloses an encapsulating material for a solar cell, and comprising an ethylene/α-olefin copolymer satisfying the following requirements (a1) to (a4): (a1) the content ratio of structural units derived from ethylene from 80 to 90 mol %, and the content ratio of structural units derived from the α-olefin (C3-C20) from 10 to 20 mol %; (a2) the MFR from 2 g/10 minutes to less than 10 g/10 minutes; (a3) the density from 0.865 to 0.884 g/cm³; and (a4) the shore A hardness from 60 to 85. The encapsulating material also contains a peroxide and a silane coupling agent. Preferred peroxides include dilauroyl peroxide; 1,1,3,3-tetramethyl butylperoxy-2-ethyl-hexanoate; dibenzoyl peroxide; t-amylperoxy-2-ethylhexanoate; t-butylperoxy-2-ethyl-hexanoate; t-butylperoxyisobutyrate; t-butylperoxy maleate; 1,1-di-(t-amylperoxy)-3,3,5-trimethylcyclohexane; 1,1-di-(t-amyl-peroxy)cyclohexane; t-amylperoxyisononanoate, t-amylperoxy-n-octoate; 1,1-di-(t-butyl-peroxy)-3,3,5-trimethylcyclohexane; 1,1-di-(t-butyl-peroxy) cyclohexane; t-butylperoxy-isopropyl carbonate; t-butylperoxy-2-ethylhexyl carbonate; 2,5-dimethyl-2,5-di-(benzoyl-peroxy) hexane; t-amyl-peroxy benzoate; t-butyl-peroxy acetate; t-butylperoxy isononanoate; 2,2-di (t-butylperoxy) butane; t-butylperoxy benzoate; and the like. Preferred peroxides are dilauroyl peroxide, t-butylperoxy isopropyl carbonate, t-butylperoxy acetate, t-butylperoxy isononanoate, t-butylperoxy-2-ethylhexyl carbonate, t-butylperoxy benzoate, and the like (see paragraph [0098]).

European Application EP2747150A1 discloses an encapsulating material for a solar cell, and which contains an ethylene/α-olefin copolymer and a specific peroxyketal having a 1-hour half-life temperature in a range of 100° C. to 135° C. The peroxyketal is contained in an amount of 0.1 to less than 0.8 weight parts, relative to 100 weight parts of the ethylene/α-olefin copolymer. The ethylene/α-olefin copolymer satisfying the following features: a1) a shore A hardness is from 60 to 85 (ASTM D2240), a2) an MFR is from 2 to 50 g/10 minutes (190 C, 2.16 kg, ASTM D1238). See abstract.

K, Thaworn et al., Effects of Organic Peroxides on the Curing Behavior of EVA Encapsulant Resin, Open Journal of Polymer Chemistry, 2012, 2, 77-85, discloses the cure of poly(ethylene-co-vinyl acetate) (EVA) with three different organic peroxides, namely, dialkyl peroxide, peroxyester peroxide, and peroxyketal peroxide. The dynamic curing, obtained by the torque rheometer, showed that dialkyl peroxide was not suitable, because it has a high half-life temperature, and its by-products can discolor the final product. Peroxyester peroxide was good for curing at temperatures in the range of 150° C. to 160° C., for an ultimate cure within S to 8 minutes. The peroxyketal peroxide had higher performance, which decreased the optimum cure time to 3 minutes. The thermal decomposition mechanism of organic peroxide was used to explain how the cure behavior is affected by generated free radicals. See abstract.

WO 2011/033232 (Abstract) discloses a composition containing the following: a) a copolymer made of ethylene and an ethylene monomer and having a polar function, and b) at least one organic peroxide solution selected from tert-butyl 2-etbylperhexanoate, tert-amyl 2-ethylperhexanoate, and dilauroyl peroxide. The amount, by weight, of the peroxide solution ranged from 5% to 30% of the total weight of the composition. The crosslinked composition is disclosed as useful as a photovoltaic cell encapsulant (see abstract). See also U.S. Publication 2012/0273718.

Additional polymers and/or peroxides are disclosed in the following references: U.S. Patent 8581094, WO 2019/136823 (abstract), CN106833406A (machine translation), CN108517188A (machine translation), J. Kruzelak, et al., Vulcanization of Rubber Compounds with Peroxide Curing Systems, Rubber Chemistry and Technology, 90(1), 60-88, 2017; J. Meijer et al., Organic Peroxides in Radical Synthesis Reactions, Acros Organics, Review 6.

However, as discussed above, there remains a need for new olefin-based polymer compositions, and related crosslinking processes, for improved cure performance. This need has been met by the follow invention.

### SUMMARY OF THE INVENTION

In a first aspect, a process to form a crosslinked composition, the process comprising applying heat, and optionally radiation, to a composition that comprises at least the following components a) and b):
a) an olefin-based polymer that comprises a total unsaturation ≥0.20/1000 C;
b) at least one peroxide selected from at least one of the following:
   i) a peroxide comprising at least one peroxy group comprising an oxyl radical unit selected from Radical I, or
   ii) a peroxide comprising at least one peroxy group comprising an oxyl radical unit selected from Radical II, or
   iii) a peroxide comprising at least one peroxy group comprising an oxyl radical unit selected from Radical III, or
   iv) a peroxide comprising at least one peroxy group comprising an oxyl radical unit selected from Radical IV, or
   v) any combination of i) through iv); and wherein Radical I, Radical II, Radical III or Radical IV are each shown below:

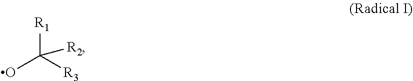

wherein R1, R2 and R3 are each independently selected from H, CH₃, CH₂-Alkyl, or Aryl; and each of R1, R2 and R3 may be the same or different from one or both of the other two; and at least one of R1, R2 or R3 is CH₂-Alkyl;

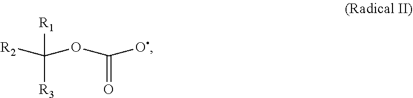

wherein R1, R2 and R3 are each independently selected from H, CH₃, CH₂-Alkyl or Aryl; and each of R1, R2 and R3 may the same or different from one or both of the other two; and at least one of R1, R2 or R3 is CH₂-Alkyl;

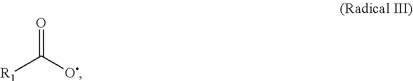

wherein R1 is CH₂-Alkyl;

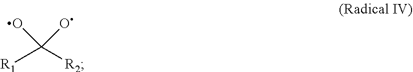

wherein R1 and R2 are selected from the following y) or z):
y) R1 and R2 are each independently CH₃, or CH₂-Alkyl; and R1 and R2 may be the same or different; and at least one of R1 or R2 is CH₂-Alkyl; or
z) R1 and R2 are bonded together to form an aliphatic ring; and wherein the ring comprises at least one —CH₂— structure adjacent to the quaternary carbon (R1—C(O·)(O·)—R2). In a second aspect, a composition that comprises at least the following components a) and b):
a) an olefin-based polymer that comprises a total unsaturation ≥0.20/1000 C;
b) at least one peroxide selected from at least one of the following:
   i) a peroxide comprising at least one peroxy group comprising an oxyl radical unit selected from Radical I, or
   ii) a peroxide comprising at least one peroxy group comprising an oxyl radical unit selected from Radical II, or
   iii) a peroxide comprising at least one peroxy group comprising an oxyl radical unit selected from Radical III, or
   iv) a peroxide comprising at least one peroxy group comprising an oxyl radical unit selected from Radical IV, or
   v) any combination of i) through iv); and
      wherein Radical I, Radical II, Radical III or Radical IV are each shown below:

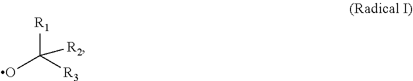

wherein R1, R2 and R3 are each independently selected from H, CH₃, CH₂-Alkyl, or Aryl; and each of R1, R2 and R3 may be the same or different from one or both of the other two; and at least one of R1, R2 or R3 is CH₂-Alkyl;

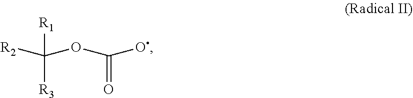

wherein R1, R2 and R3 are each independently selected from H, CH₃, CH₂-Alkyl or Aryl; and each of R1, R2 and R3 may the same or different from one or both of the other two; and at least one of R1, R2 or R3 is CH₂-Alkyl;

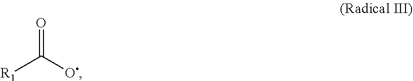

wherein R1 is CH₂-Alkyl;

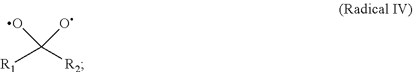

wherein R1 and R2 are selected from the following y) or z):
y) R1 and R2 are each independently CH₃, or CH₂-Alkyl; and R1 and R2 may be the same or different; and at least one of R1 or R2 is CH₂-Alkyl; or
z) R1 and R2 are bonded together to form an aliphatic ring; and wherein the ring comprises at least one —CH₂— structure adjacent to the quaternary carbon (R1—C(O·)(O·)—R2).

### DETAILED DESCRIPTION OF THE INVENTION

Olefin-based polymer compositions have been discovered that have good cure rates, without sacrificing the level of cure. As discussed above, in a first aspect, a process to form a crosslinked composition is provided, as discussed above. In a second aspect, a composition is provided, as discussed above. Each process may comprise a combination of two or more embodiments, as described herein. Each composition may comprise a combination of two or more embodiments, as described herein. Each component a and b may comprise a combination of two or more embodiments, as described herein. The following embodiments apply to both the first and second aspects unless noted.

In one embodiment, or a combination of two or more embodiments, each described herein, component b is a peroxide comprising at least one peroxy group comprising an oxyl radical unit selected from Radical I.

In one embodiment, or a combination of two or more embodiments, each described herein, component b is a peroxide comprising at least one peroxy group comprising an oxyl radical unit selected from Radical II.

In one embodiment, or a combination of two or more embodiments, each described herein, component b is a peroxide comprising at least one peroxy group comprising an oxyl radical unit selected from Radical III.

In one embodiment, or a combination of two or more embodiments, each described herein, component b is a peroxide comprising at least one peroxy group comprising an oxyl radical unit selected from Radical IV.

In one embodiment, or a combination of two or more embodiments, each described herein, component b is selected from the following structures r1) through r132), each as described below (see V] below).

In one embodiment, or a combination of two or more embodiments, each described herein, the peroxide is present in an amount ≥0.10 wt %, or ≥0.20 wt % , or ≥0.30 wt %, or ≥0.40 wt %, or ≥0.50 wt %, or ≥0.52 wt %, or ≥0.54 wt, and/or ≤2.00 wt %, or ≤1.80 wt %, or ≤1.60 wt %, or ≤1.40 wt %, or ≤1.20 wt %, or ≤1.00 wt %, based on the weight of the composition.

In one embodiment, or a combination of two or more embodiments, each described herein, the composition comprises ≥50.0 wt %, or ≥60.0 wt %, or ≥70.0 wt %, or ≥80.0 wt %, or ≥85.0 wt %, or ≥90.0 wt %, or ≥95.0 wt %, or ≥98.0 wt %, or ≥99.0 wt %, or ≥99.2 wt %, and/or ≤100.0 wt %, or ≤99.9 wt %, or ≤99.8 wt %, or ≤99.7 wt %, or ≤99.6 wt %, of the sum of components a and b, based on the weight of the composition.

In one embodiment, or a combination of two or more embodiments, each described herein, the weight ratio of component a to component bis ≥50, or ≥60, or ≥70, or ≥80, or ≥90, or ≥100 and/or ≤200, or ≤190, or ≤180, or ≤170, or ≤160, or ≤150, or ≤145, or ≤140, or ≤135, or ≤130.

In one embodiment, or a combination of two or more embodiments, each described herein, component a has a total unsaturation ≥0.22/1000 C, or ≥0.24/1000 C, or ≥0.26/1000 C, or ≥0.28/1000 C, or ≥0.30/1000 C, or ≥0.35/1000 C, or ≥0.40/1000 C, or ≥0.45/1000 C, or ≥0.50/1000 C, or ≥0.55/1000 C, or ≥0.60/1000 C, or ≥0.65/1000 C, and/or ≤15.0/1000 C, or ≤10.0/1000 C, or ≤5.00/1000 C, or ≤2.00/1000 C, or ≤1.80/1000 C, or ≤1.60/1000 C, or ≤1.50/1000 C, or ≤1.40/1000 C, or ≤1.30/1000 C, or ≤1.20/1000 C, or ≤1.10/1000 C, or ≤1.00/1000 C.

In one embodiment, or a combination of two or more embodiments, each described herein, component a is an ethylene-based polymer.

In one embodiment, or a combination of two or more embodiments, each described herein, component a is selected from a telechelic polyolefin of the formula A¹L¹L²A², an unsaturated polyolefin of the formula A¹L¹, an ethylene/alpha-olefin/nonconjugated polyene interpolymer, or an ethylene/alpha-olefin interpolymer.

In one embodiment, or a combination of two or more embodiments, each described herein, component a has a density ≥0.854, or ≥0.856, or ≥0.858, or ≥0.860, or ≥0.862, or ≥0.864, or ≥0.866, or ≥0.868, or ≥0.870 g/cc, and/or ≤0.960, or ≤0.955, or ≤0.950, or ≤0.945, or ≤0.940, or ≤0.935, or ≤0.930, or ≤0.925, or ≤0.920, or ≤0.915, or ≤0.910, or ≤0.905, or ≤0.900, or ≤0.895, or ≤0.890, or ≤0.885, or ≤0.880, or ≤0.878, or ≤0.876, or ≤0.875, or ≤0.874 g/cc (1 cc =1 cm³).

In one embodiment, or a combination of two or more embodiments, each described herein, component a has a molecular weight distribution MWD (=Mw/Mn) ≥1.80, or ≥1.90, or ≥2.00, or ≥2.10, or ≥2.15, or ≥2.20, or ≥2.25, or ≥2.30, or ≥2.35, or ≥2.40, and/or ≤5.00, or ≤4.80, or ≤4.60, or ≤4.40, or ≤4.20 or ≤4.00, or ≤3.80, or ≤3.60, or ≤3.40 or ≤3.20, or ≤3.0.

In one embodiment, or a combination of two or more embodiments, each described herein, the composition has a percent change (Δ) in T90, as described herein, ≥−80%, or ≥−70%, or ≥−65%, or ≥−60%, or ≥−55%, or ≥−50%, or ≥−45%, or ≥−40%, and/or ≤−10%, or ≤−15%, ≤−20%, or ≤−25%, or ≤−30%.

In one embodiment, or a combination of two or more embodiments, each described herein, the composition has a percent change (A) in MH, as described herein, ≥−40%, or ≥−35%, or ≥−30%, or ≥−25%, ≥−20%, or ≥−15%, or ≥−10%, or ≥−5.0%, or ≥0%, or ≥2.0%, or ≥4.0%, or ≥6.0%, or ≥8.0%, and/or ≤400%, or ≤350%, or ≤300%, or ≤250%, or ≤200%, or ≤150%, or ≤100%, or ≤90%, or ≤80%, or ≤70%, or ≤60%, or ≤50%, or ≤40%, or ≤30%, or ≤20%, or ≤10%.

Also provided is a crosslinked composition formed from a process of one or more embodiments as described herein, or from a composition of one or more embodiments as described herein.

Also provided is an article comprising at least one component formed from a composition of one or more embodiments as described herein.

### Olefin-Based Polymers

Olefin-based polymers include, but are not limited to, elastomers and other olefin-based polymers. An elastomer is a polymer with viscoelastic (i.e., both viscosity and elasticity) properties. An olefin-based polymer includes, but is not limited to, the following: an ethylene/alpha-olefin/nonconjugated polyene interpolymer; a telechelic polyolefin of the formula A¹L¹L²A², an unsaturated polyolefin of the formula A¹L¹, an ethylene/alpha-olefin interpolymer.

The ethylene/alpha-olefin/nonconjugated polyene interpolymers, as described herein, comprises, in polymerized form, ethylene, an alpha-olefin, and a nonconjugated polyene. The alpha-olefin may be either an aliphatic or an aromatic compound. Alpha-olefins include, but are not limited to, C3-C20 alpha-olefins, further C3-C10 alpha-olefins, further C3-C8 alpha-olefins. In one embodiment, the interpolymer is an ethylene/propylene/nonconjugated diene interpolymer, further an EPDM. Suitable examples of nonconjugated polyenes include the C4-C40 nonconjugated dienes. Nonconjugated dienes include, but are not limited to, 5-ethylidene-2-norbornene (ENB), 5-vinyl-2-norbornene (VNB), dicyclopentadiene, 1,4-hexadiene, or 7-methyl-1,6-octadiene, and further ENB, VNB, dicyclopentadiene or 1,4-hexadiene, and further ENB or VNB, and further ENB.

The ethylene/alpha-olefin interpolymer comprises, in polymerized form, ethylene, and an alpha-olefin. Alpha-olefins include, but are not limited to, a C3-C20 alpha-olefins, further C3-C10 alpha-olefins, further C3-C8 alpha-olefins, such as propylene, 1-butene, 1-hexene, and 1-octene.

Telechelic polyolefins, such as those of the A¹L¹L²A² (Formula I), and unsaturated polyolefins, such as those of the A¹L¹ (Formula II), are each described below. See also WO 2020/140058 and WO 2020/140067, each incorporated herein by reference.

Telechelic polyolefin of Formula I: A¹L¹L²A², wherein:
L1 is a polyolefin, and preferably an ethylene-based polymer, and further an ethylene/alpha-olefin interpolymer, and further an ethylene/alpha-olefin copolymer; note, L¹ (divalent) is bonded to A¹ and L².
A¹ is selected from the group consisting of the following:
a) a vinyl group, b) a vinylidene group of the formula CH₂═C(Y¹)—, c) a vinylene group of the formula Y¹CH═CH—, d) a mixture of a vinyl group and a vinylene group of the formula Y¹CH═CH—, e) a mixture of a vinyl group and a vinylidene group of the formula CH₂═C(Y¹)—, f) a mixture of a vinylidene group of the formula CH₂═C(Y¹)— and a vinylene group of the formula Y¹CH═CH—, and g) a mixture of a vinyl group, a vinylidene group of the formula CH₂═C(Y¹)—, and a vinylene group of the formula Y¹CH═CH—;
Y¹ at each occurrence, independently, is a C₁ to C₃₀ hydrocarbyl group,
L² is a C₁ to C₃₂ hydrocarbylene group; and
A² is a hydrocarbyl group comprising a hindered double bond.

Unsaturated polyolefin of Formula II: A¹L¹, wherein:
L′ is polyolefin, and preferably an ethylene-based polymer, and further an ethylene/alpha-olefin interpolymer, and further an ethylene/alpha-olefin copolymer; note, L¹ (monovalent) is bonded to A¹;
A¹ is selected from the group consisting of the following: a) a vinyl group, b) a vinylidene group of the formula CH₂═C(Y¹)—, c) a vinylene group of the formula Y¹CH═CH—, d) a mixture of a vinyl group and a vinylene group of the formula Y¹CH═CH—, e) a mixture of a vinyl group and a vinylidene group of the formula CH₂═C(Y¹)—, f) a mixture of a vinylidene group of the formula CH₂═C(Y¹)— and a vinylene group of the formula Y¹CH═CH—, and g) a mixture of a vinyl group, a vinylidene group of the formula CH₂═C(Y¹)—, and a vinylene group of the formula Y¹CH═CH—; and Y1 at each occurrence, independently, is a C₁ to C₃₀ hydrocarbyl group.

For Formula I and Formula II, L¹ at each occurrence independently is a polyolefin, as described above, and may result, in part, from the polymerization (for example, coordination polymerization) of unsaturated monomers (and comonomers). Examples of suitable monomers (and comonomers) include, but are not limited to, ethylene and alpha-olefins of 3 to 30 carbon atoms, further 3 to 20 carbon atoms, such as, for example, propylene, 1-butene, 1-pentene, 3-methyl-1-butene, 1-hexene, 4-methyl-1-pentene, 3-methyl-1-pentene, 3,5,5-trimethyl-lhexene, 1-octene, 1-decene, 1-dodecene, 1-tetradecene, 1-hexadecene, 5-ethyl-1-nonene, 1-octadecene and 1-eicosene; conjugated or nonconjugated dienes, such as, for example, butadiene, isoprene, 4-methyl-1,3-pentadiene, 1,3-pentadiene, 1,4-pentadiene, 1,5-hexadiene, 1,4-hexadiene, 1,3-hexadiene, 1,5-heptadiene, 1,6-heptadiene, 1,3-octadiene, 1,4-octadiene, 1,5-octadiene, 1,6-octadiene, 1,7-octadiene, 1,9-decadiene, 7-methyl- 1,6-octadiene, 4-ethylidene-8-methyl-1,7-nonadiene, and 5,9-dimethyl-1,4,8-decatriene, 5-methyl-1,4-hexadiene, 3,7-dimethyl-1,6-octadiene, 3,7-dimethyl-1,7-octadiene, and mixed isomers of dihydromyrcene and dihydroocimene; norbornene and alkenyl, alkylidene, cycloalkenyl and cycloalkylidene norbornenes, such as 5-ethylidene-2-norbornene, 5-vinyl-2-norbornene, dicyclopentadiene, 5-methylene-2-norbornene, 5-propenyl-2-norbornene, 5-isopropylidene-2-norbornene, 5-(4-cyclopentenyl)-2-norbornene, 5-cyclohexylidene-2-norbornene, and norbornadiene; and aromatic vinyl compounds such as styrenes, mono or polyalkylstyrenes (including styrene, o-methylstyrene, t-methylstyrene, m-methylstyrene, p-methylstyrene, o-dimethylstyrene, o-ethylstyrene, m-ethylstyrene and p-ethylstyrene).

### Peroxides

As used herein, a peroxide contains at least one oxygen-oxygen bond (O—O). Useful peroxides include, but are not limited to, peroxycarbonates, such as, for example, tert-amylperoxy-2-ethylhexyl carbonate (TAEC); and peroxyketals, such as, for example, 1,1-di(tert-amylperoxy)cyclohexane. See also structures r1) to r132) described below.

### Additives

An inventive composition may comprise one or more additives. Additives include, but are not limited to, one or more alkoxyl silanes coupling agents, such as vinyltrimethoxy-silane (VTMS) or 3-(trimethoxysilyl)-propyl-methacrylate (VMMS) or alkoxyl silane coupling agent combinations; tetra ethoxyl silane TEOS (or pre-hydrolyzed products); and crosslinking coagents, such as triallyl isocyanurate (TAIC), triallyl cyanurate (TAC), triallyl trimellitate (TATM), trimethylolpropane triacylate (TMPTA), trimethylolpropane trimethylacrylate (TMPTMA), 1,6-hexanediol diacrylate, pentaerythritol tetraacrylate, dipentaerythritol penta acrylate, tris (2-hydroxy ethyl) isocyanurate triacrylate, trivinyl cyclohexane (TVCH), or combinations thereof. Additional coagents include alkenyl-functional monocyclic organosiloxanes, as disclosed in WO 2019/000311 and WO 2019/000654, which are incorporated herein by reference in their entirety (for example, a monocyclic organosiloxane of the formula [R1,R2SiO2/2]n, wherein subscript n is an integer greater than or equal to 3; each R1 is independently a (C2-C4)alkenyl or a H₂C═C(R1a)—C(═O)—O—(CH₂)m— wherein R1a is H or methyl and subscript m is an integer from 1 to 4; and each R2 is independently H, (C1-C4)alkyl, phenyl, or R1; for example 2,4,6,8-tetramethyl-2,4,6,8-tetravinyl cyclotetrasiloxane, 2,4,6-trimethyl-2,4,6-trivinyl-cyclotrisiloxane, or a combination thereof).

Additional additives include UV absorbers and/or stabilizers, such as TINUVIN 770;

one or more anti-oxidants; processing aids, such as fluoro polymers, polydimethylsiloxane (PDMS), ultra-high molecular weight PDMS; ion scavengers, anti PID agents; other siloxanes; fumed silica, nano Al₂O₃, nano-clay, and one or more other fillers. In one embodiment, an additive is present in an amount ≥0.20 wt %, or ≥0.40 wt %, or ≥0.60 wt %, or ≥0.80 wt %, and/or ≤5.0 wt %, or ≤4.0 wt %, or ≤3.0 wt %, or ≤2.0 wt %, or ≤1.5 wt %, or ≤1.0 wt %, based on the weight of the composition.

### DEFINITIONS

Unless stated to the contrary, implicit from the context, or customary in the art, all parts and percentages are based on weight, and all test methods are current as of the filing date of this disclosure.

The term “composition,” as used herein, includes a mixture of materials, which comprise the composition, as well as reaction products and decomposition products formed from the materials of the composition. Any reaction product or decomposition product is typically present in trace or residual amounts.

The term “polymer,” as used herein, refers to a polymeric compound prepared by polymerizing monomers, whether of the same or a different type. The generic term polymer includes the term homopolymer (employed to refer to polymers prepared from only one type of monomer, with the understanding that trace amounts of impurities can be incorporated into the polymer structure), and the term interpolymer as defined hereinafter. Trace amounts of impurities, such as catalyst residues, can be incorporated into and/or within the polymer. Typically, a polymer is stabilized with very low amounts (“ppm” amounts) of one or more stabilizers.

The term “interpolymer,” as used herein, refers to a polymer prepared by the polymerization of at least two different types of monomers. The term interpolymer thus includes the term copolymer (employed to refer to polymers prepared from two different types of monomers) and polymers prepared from more than two different types of monomers.

The term “olefin-based polymer,” as used herein, refers to a polymer that comprises, in polymerized form, 50 wt % or a majority weight percent of an olefin, such as, for example, ethylene or propylene (based on the weight of the polymer), and optionally may comprise one or more comonomers. As used herein, olefin-based polymers include, but are not limited to, ethylene/alpha-olefin/nonconjugated polyene interpolymers, telechelic polyolefins of the formula A¹L¹L²A², unsaturated polyolefins of the formula A¹L¹, and ethylene/alpha-olefin interpolymers.

The term “polyolefin,” as used herein, refers to a polymer that comprises, in polymerized form, 50 wt % or a majority weight percent of an olefin, such as ethylene or propylene (based on the weight of the polymer), and optionally may comprise one or more comonomers.

The term “propylene-based polymer,” as used herein, refers to a polymer that comprises, in polymerized form, a majority weight percent of propylene (based on the weight of the polymer), and optionally may comprise one or more comonomers.

The term “ethylene-based polymer,” as used herein, refers to a polymer that comprises, in polymerized form, 50 wt % or a majority weight percent of ethylene (based on the weight of the polymer), and optionally may comprise one or more comonomers.

The term “ethylene/alpha-olefin interpolymer,” as used herein, refers to an interpolymer that comprises, in polymerized form, 50 wt % or a majority weight percent of ethylene (based on the weight of the interpolymer), and an alpha-olefin. Preferably, the ethylene/alpha-olefin interpolymer is a random interpolymer (i.e., comprises a random distribution of its monomeric constituents).

The term, “ethylene/alpha-olefin copolymer,” as used herein, refers to a copolymer that comprises, in polymerized form, 50 wt % or a majority weight percent of ethylene (based on the weight of the copolymer), and an alpha-olefin, as the only two monomer types. Preferably, the ethylene/alpha-olefin copolymer is a random copolymer (i.e., comprises a random distribution of its monomeric constituents).

The term “ethylene/alpha-olefin/nonconjugated polyene interpolymer,” as used herein, refers to an interpolymer that comprises, in polymerized form, ethylene, an alpha-olefin, and a nonconjugated polyene. In one embodiment, the “ethylene/alpha-olefin/non-conjugated polyene interpolymer,” comprises, in polymerized form, 50 wt % or a majority weight percent of ethylene (based on the weight of the interpolymer). The term “ethylene/alpha-olefin/nonconjugated diene interpolymer,” as used herein, refers to a random interpolymer that comprises, in polymerized form, ethylene, an alpha-olefin, and a nonconjugated diene. In one embodiment, the “ethylene/alpha-olefin/nonconjugated diene interpolymer,” comprises, in polymerized form, 50 wt % or a majority weight percent of ethylene (based on the weight of the interpolymer). Note, the terms “ethylene/alpha-olefin/nonconjugated polyene terpolymer” and “ethylene/alpha-olefin/nonconjugated diene terpolymer” are similarly defined; however, for each, the terpolymer comprises, in polymerized form, ethylene, the alpha-olefin and the polyene (or diene) as the only three monomer types.

The phrase “a majority weight percent,” as used herein, in reference to a polymer (or interpolymer, or terpolymer or copolymer), refers to the amount of monomer present in the greatest amount in the polymer.

The term “crosslinked composition,” as used herein, refers to a composition that has a network structure due to the formation of chemical bonds between polymer chains. The degree of formation of this network structure is indicated by an increase in the “MH-ML” differential, relative to the non-crosslinked composition. A crosslinked composition typically has a gel content ≥50 wt %, further ≥60 wt %, further ≥70 wt %, further ≥80 wt %, based on the weight of the crosslinked composition. See Gel Test below.

The phrases “applying heat,” “heat treated,” “heat treatment,” and similar terms, as used herein, in reference to a composition comprising an olefin-based polymer as discussed herein, refer to heating the composition. Heat may be applied by electrical means (for example, a heating coil). Note, the temperature at which the heat treatment takes place, refers to the temperature of the composition (for example, the cure temperature of the composition).

The phrases “applying radiation,” “radiation treating,” “radiation treatment,” and similar terms, as used herein, in reference to a composition comprising an olefin-based polymer as discussed herein, refer to the exposure of the composition to radiation (for example, high-energy electron beam or UV).

The phrases “thermally treating,” “thermal treatment,” and similar terms, as used herein, in reference to a composition comprising an olefin-based polymer as discussed herein, refer to increasing the temperature of the composition by the application of heat, radiation or other means (for example, a chemical reaction), and preferably by the application of heat. Note, the temperature at which the thermal treatment takes place, refers to the temperature of the composition (for example, the cure temperature of the composition).

The terms “comprising,” “including,” “having,” and their derivatives, are not intended to exclude the presence of any additional component, step or procedure, whether the same is specifically disclosed. In order to avoid any doubt, all compositions claimed through use of the term “comprising” may include any additional additive, adjuvant, or compound, whether polymeric or otherwise, unless stated to the contrary. In contrast, the term, “consisting essentially of” excludes from the scope of any succeeding recitation any other component, step or procedure, excepting those that are not essential to operability. The term “consisting of” excludes any component, step or procedure, not specifically delineated or listed.

Listing of Some Processes and Compositions
A] A process to form a crosslinked composition, the process comprising applying heat, and optionally radiation, to a composition that comprises at least the following components a) and b):
   a) an olefin-based polymer that comprises a total unsaturation ≥0.20/1000 C;
   b) at least one peroxide selected from at least one of the following:
      i) a peroxide comprising at least one peroxy group comprising an oxyl radical unit selected from Radical I, or
      ii) a peroxide comprising at least one peroxy group comprising an oxyl radical unit selected from Radical II, or
      iii) a peroxide comprising at least one peroxy group comprising an oxyl radical unit selected from Radical III, or
      iv) a peroxide comprising at least one peroxy group comprising an oxyl radical unit selected from Radical IV, or
      v) any combination of i) through iv); and wherein Radical I, Radical II, Radical III or Radical IV are each shown below:

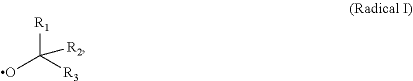

wherein R1, R2 and R3 are each independently selected from H, CH₃, CH₂-Alkyl, or Aryl; and each of R1, R2 and R3 may be the same or different from one or both of the other two; and at least one of R1, R2 or R3 is CH₂-Alkyl;

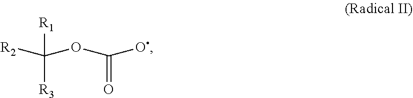

wherein R1, R2 and R3 are each independently selected from H, CH₃, CH₂-Alkyl or Aryl; and each of R1, R2 and R3 may the same or different from one or both of the other two; and at least one of R1, R2 or R3 is CH₂-Alkyl;

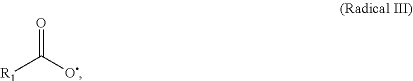

wherein R1 is CH₂-Alkyl;

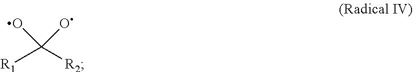

wherein R1 and R2 are selected from the following y) or z):
y) R1 and R2 are each independently CH₃, or CH₂-Alkyl; and R1 and R2 may be the same or different; and at least one of R1 or R2 is CH₂-Alkyl; or
z) R1 and R2 are bonded together to form an aliphatic ring; and wherein the ring comprises at least one —CH₂— structure adjacent to the quaternary carbon (R1—C(O·)(O·)—R2).

Note, as used herein, in reference to the noted peroxides, R1=R₁, R2=R₂, R3=R₃, etc.. It is understood two oxyl radicals (for example, R—O·) are bonded together to form a peroxy group (O—O) in the peroxide (component b).

The phrase “peroxy group comprising an oxyl radical unit selected from Radical I,” and similar phrases disclosed herein, refer to a peroxy group formed, in part, from the noted radical, which will form an —O—O— bond with another oxyl radical.

An alkyl group (Alkyl) may be linear or branched. An aryl group (Ar) may or may not comprise one or more alkyl substitutions. An aliphatic ring may or may not comprise one or more alkyl substitutions.
B] The process of A] above, wherein for Radical IV, R1 and R2 are each independently CH3, or CH2-Alkyl; and R1 and R2 could be same or the different; and at least one of R1 or R2 is CH2-Alkyl.
C] The process of A] above, wherein for Radical IV, R1 and R2 are bonded together to form an aliphatic ring; and where the ring comprises at least one —CH₂— structure adjacent to the quaternary carbon (R1—C(O·)(O·)—R2).
D] The process of A] or C] above, wherein for Radical IV, the ring structure comprises from 5 to 15 carbon atoms, further from 5 to 9 carbon atoms.
E] The process of A] above, wherein component b is a peroxide comprising at least one peroxy group comprising an oxyl radical unit selected from Radical I. For example, see structures r1)-r68), r76)-r78) below.
F] The process of A] above, wherein component b is a peroxide comprising at least one peroxy group comprising an oxyl radical unit selected from Radical II. For example, see structures r13)-r28), r31), r32), r34)-r44), r123), r129)-r132) below.
G] The process of A] above, wherein component b is a peroxide comprising at least one peroxy group comprising an oxyl radical unit selected from Radical III. For example, see structures r46), r51)-r68), r124)-r128) below.
H] The process of any one of A]-D] above, wherein component b is a peroxide comprising at least one peroxy group comprising an oxyl radical unit selected from Radical IV. For example, see structures r69)-193) below.
I] The process of any one of A]-D] above, wherein component b is a peroxide comprising multiple peroxy groups formed from at least two oxyl radical units independently selected from Radical IV to form a cyclic structure. Further, each radical unit is the same. For example, see r94)-r99) below.
J] The process of any one of A]-D] or I] above, wherein component b is a peroxide comprising multiple peroxy groups formed from at least three oxyl radical units independently selected from Radical IV to form a cyclic structure. Further, each radical unit is the same. For example, see r96)-r99) below.
K] The process of any one of A]-D] above, wherein component b is a peroxide comprising at least two peroxy groups formed from at least two oxyl radical units independently selected from Radical IV to form a non-cyclic structure. Further, each radical unit is the same. For example, see r100)-r122) below.
L] The process of any one of A]-D] or K] above, wherein component b is a peroxide comprising at least three peroxy groups formed from at least three oxyl radical units independently selected from Radical IV to form a non-cyclic structure. Further, each radical unit is the same. For example, see r100)-r110, r121), r122) below.
M] The process of A] above, wherein component b is a peroxide comprising at least one peroxy group formed from an oxyl a radical unit selected from Radical I and an oxyl radical unit selected from Radical II. For example, see structures r13)-r28), r31), r32), r34)-r44) below.
N] The process of A] above, wherein component b is a peroxide comprising at least one peroxy group formed from an oxyl a radical unit selected from Radical I and an oxyl radical unit selected from Radical III. For example, see structures r46), r51)-r68) below.
O] The process of A] above, wherein component b is a peroxide comprising at least one peroxy group formed from an oxyl a radical unit selected from Radical I and an oxyl radical unit selected from Radical IV. For example, see structures r70)-r73), r75)-r79), r81)-r88), r90), r93) below.
P] The process of any one of A]-O] (A] through O]) above, wherein the peroxide is present in an amount ≥0.10 wt %, or ≥0.20 wt %, or ≥0.30 wt %, or ≥0.40 wt %, or ≥0.50 wt %, or ≥0.52 wt %, or ≥0.54 wt, and/or ≤2.00 wt %, or ≤1.80 wt %, or ≤1.60 wt %, or ≤1.40 wt %, or ≤1.20 wt %, or ≤1.00 wt %, based on the weight of the composition.
Q] The process of any one of A]-P], wherein the composition comprises ≥50.0 wt %, or ≥60.0 wt %, or ≥70.0 wt %, or ≥80.0 wt %, or ≥85.0 wt %, or ≥90.0 wt %, or ≥95.0 wt %, or ≥98.0 wt %, or ≥99.0 wt %, or ≥99.2 wt %, and/or ≤100.0 wt %, or ≤99.9 wt %, or ≤99.8 wt %, or ≤99.7 wt %, or ≤99.6 wt %, of the sum of components a and b, based on the weight of the composition.
R] The process of any one of A]-Q] above, wherein component a has a total unsaturation ≥0.22/1000 C, or ≥0.24/1000 C, or ≥0.26/1000 C, or ≥0.28/1000 C, or ≥0.30/1000 C, or ≥0.35/1000 C, or ≥0.40/1000 C, or ≥0.45/1000 C, or ≥0.50/1000 C, or ≥0.55/1000 C, or ≥0.60/1000 C, or ≥0.65/1000 C, and/or ≤15.0/1000 C, or ≤10.0/1000 C, or ≤5.00/1000 C, or ≤2.00/1000 C, or ≤1.80/1000 C, or ≤1.60/1000 C, or ≤1.50/1000 C, or ≤1.40/1000 C, or ≤1.30/1000 C, or ≤1.20/1000 C, or ≤1.10/1000 C, or ≤1.00/1000 C.
S] The process of any one of A]-R] above, wherein component a is an ethylene-based polymer.
T] The process of any one of A]-S] above, wherein component a has a density ≥0.854, or ≥0.856, or ≥0.858, or ≥0.860, or ≥0.862, or ≥0.864, or ≥0.866, or ≥0.868, or ≥0.870 g/cc, and/or ≤0.960, or ≤0.955, or ≤0.950, or ≤0.945, or ≤0.940, or ≤0.935, or ≤0.930, or ≤0.925, or ≤0.920, or ≤0.915, or ≤0.910, or ≤0.905, or ≤0.900, or ≤0.895, or ≤0.890, or ≤0.885, or ≤0.880, or ≤0.875 g/cc (1 cc=1 cm³).
U] The process of any one of A]-T] above, wherein component a has a melt index (12) ≥0.1, or ≥0.2, or ≥0.5, or ≥1.0, or ≥2.0, or ≥5.0, or ≥8.0, or ≥10, or ≥15, or ≥20, or ≥25 dg/min, and/or ≤2000, or ≤1000, or ≤500, or ≤200, or ≤100, or ≤50, or ≤40, or ≤35, or ≤30 dg/min.

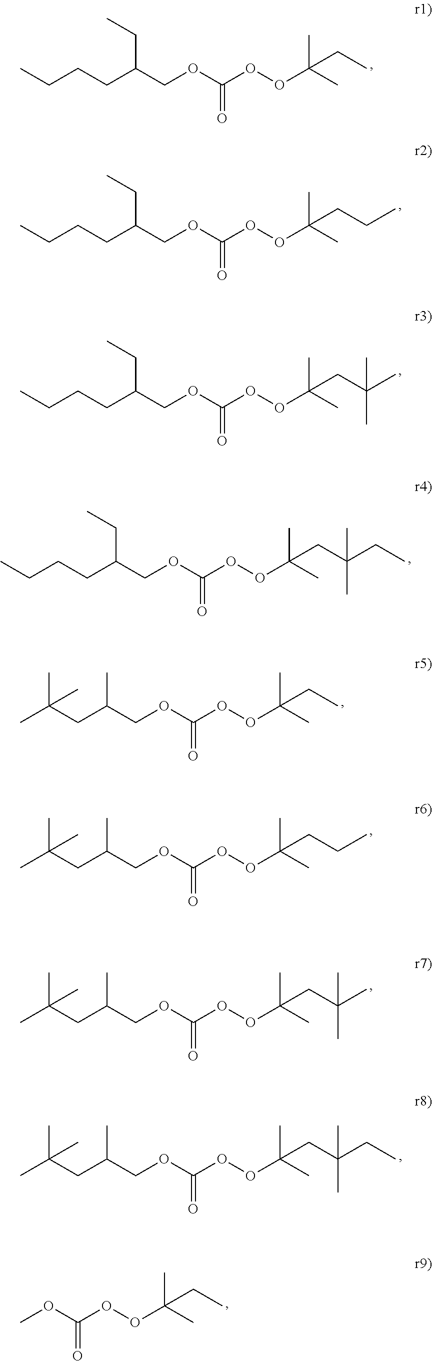

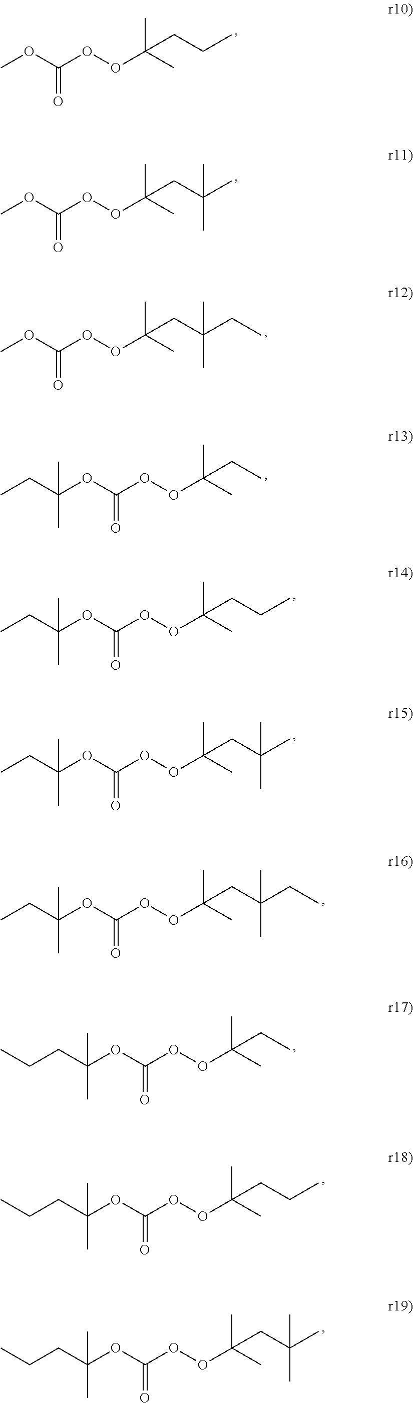

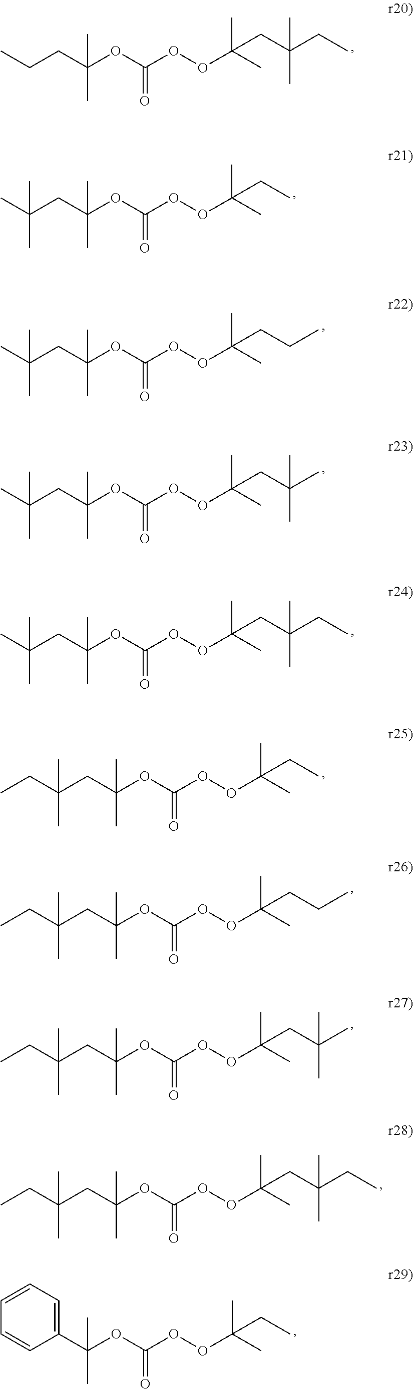

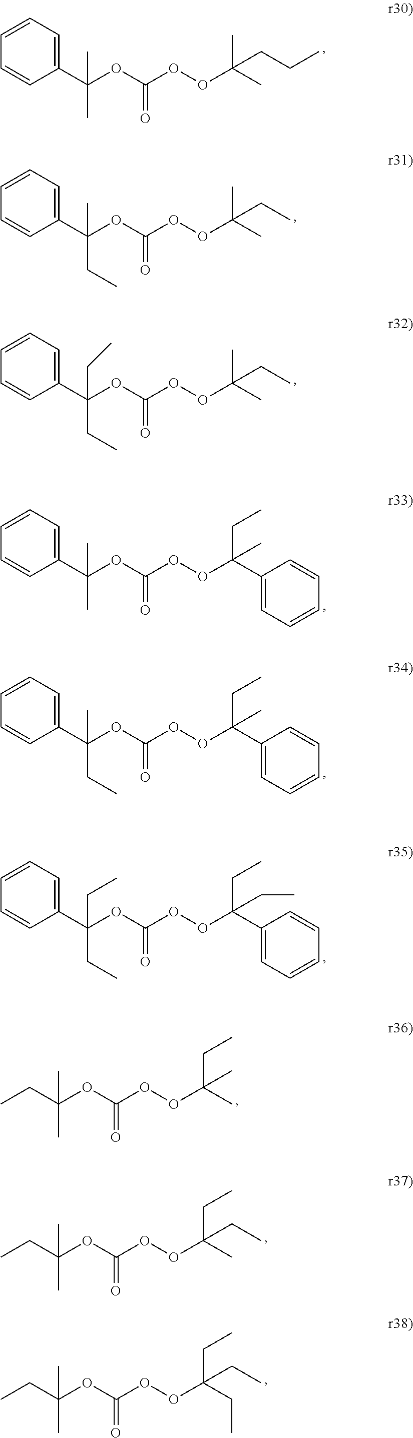

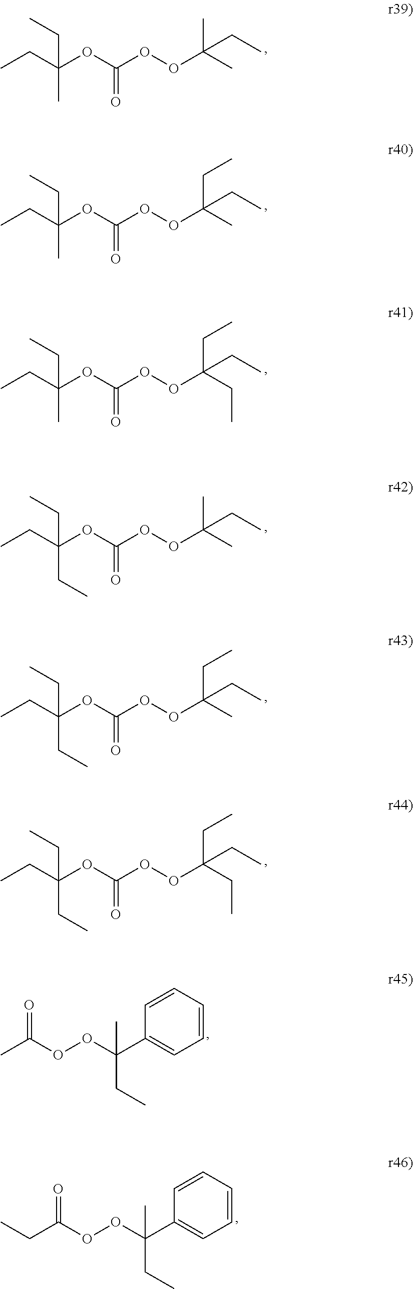

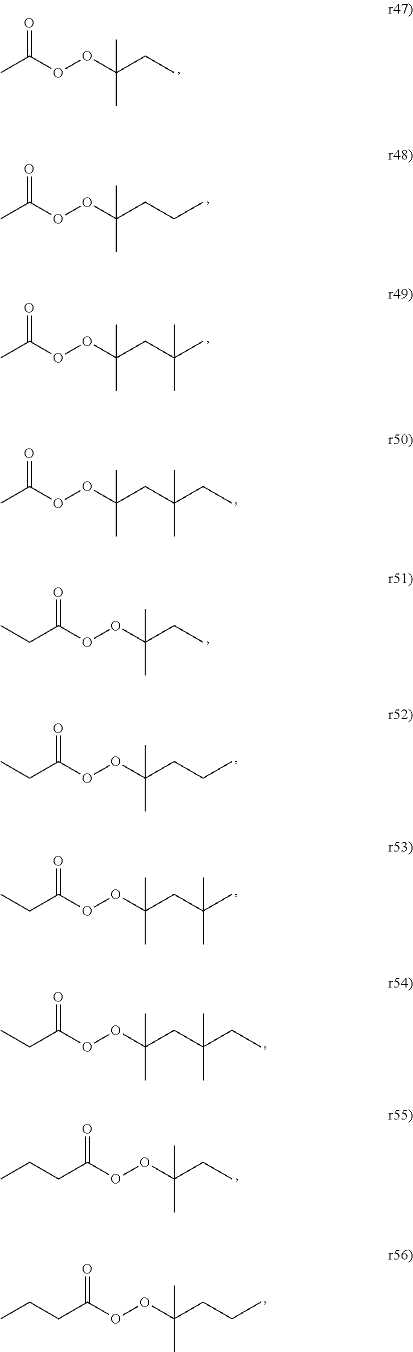

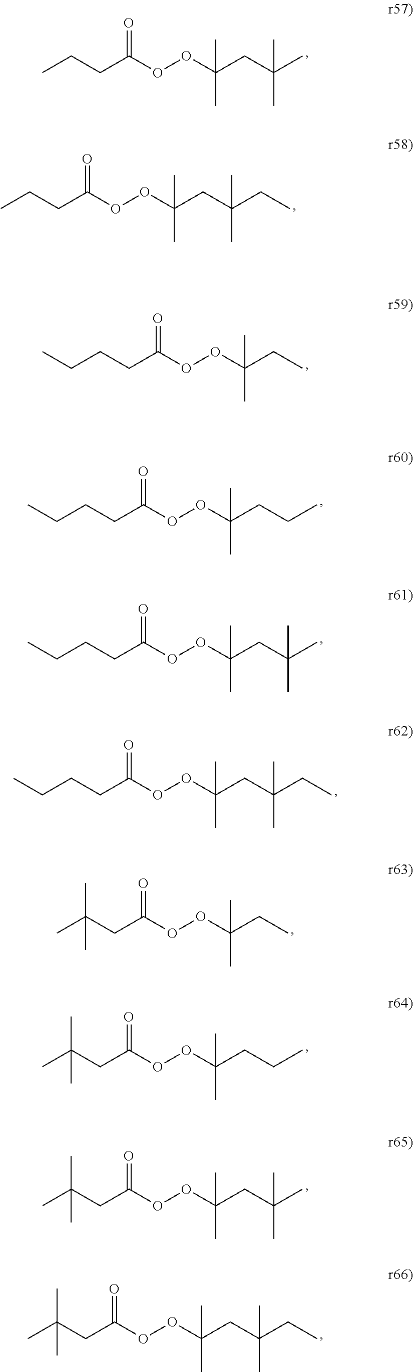

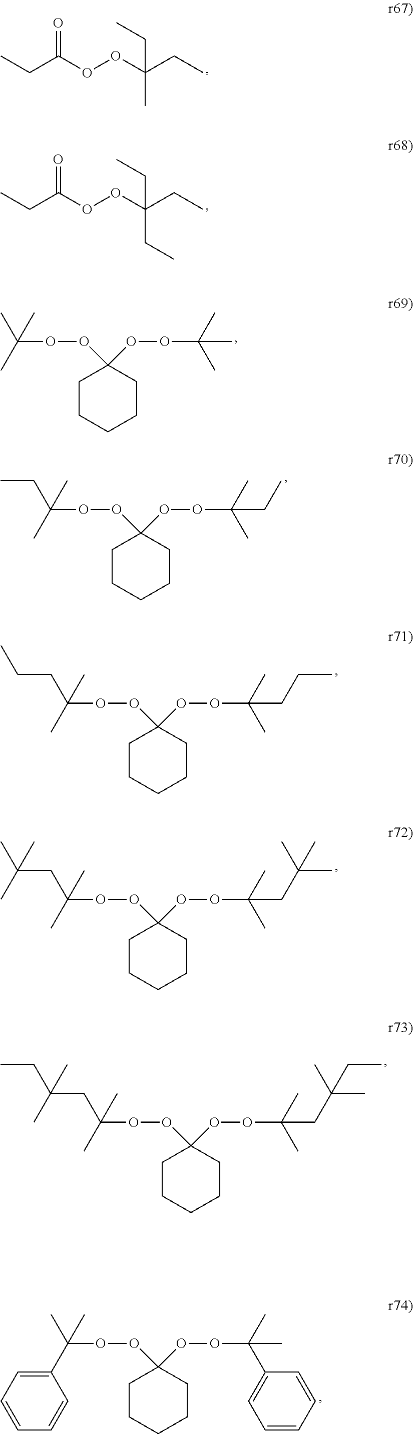

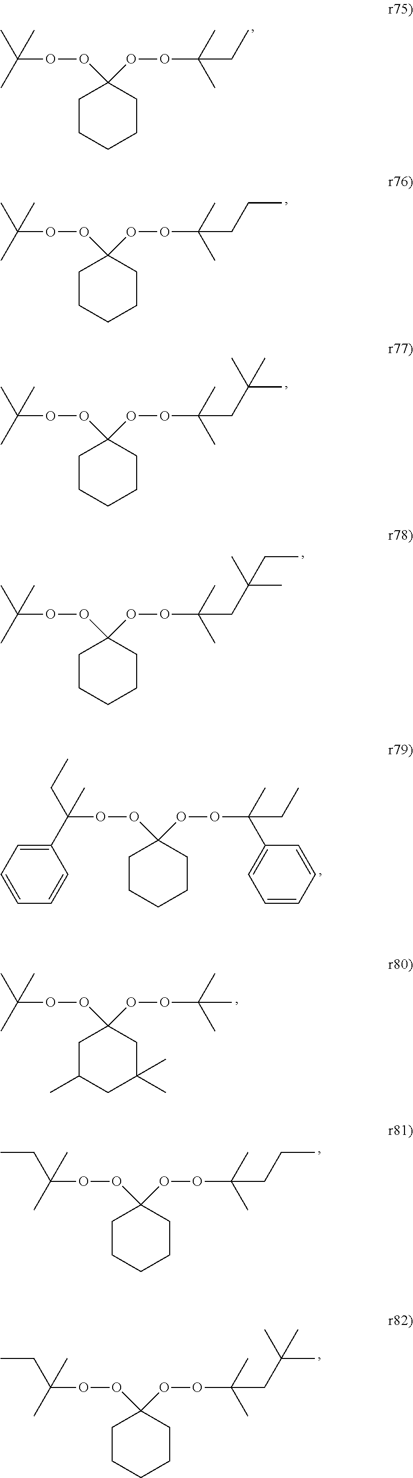

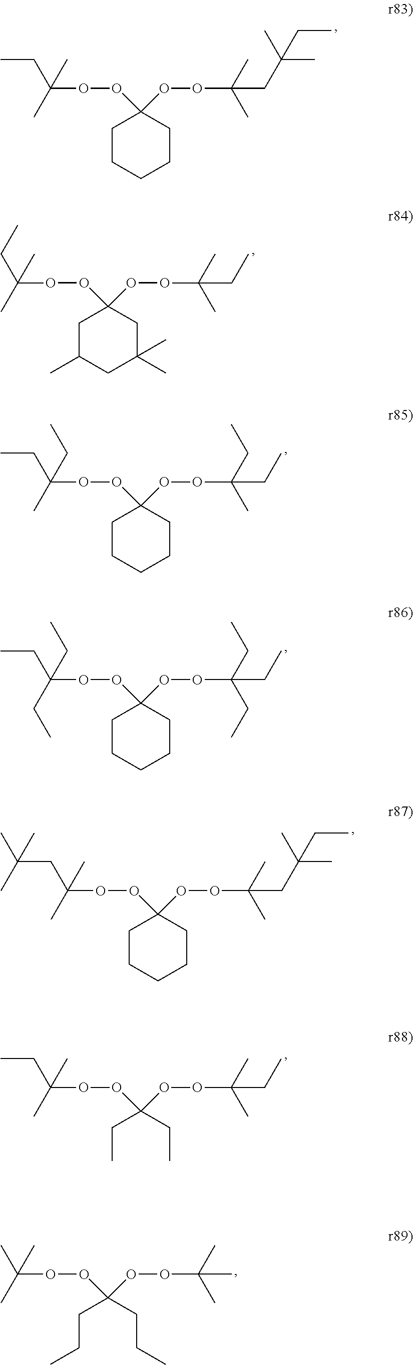

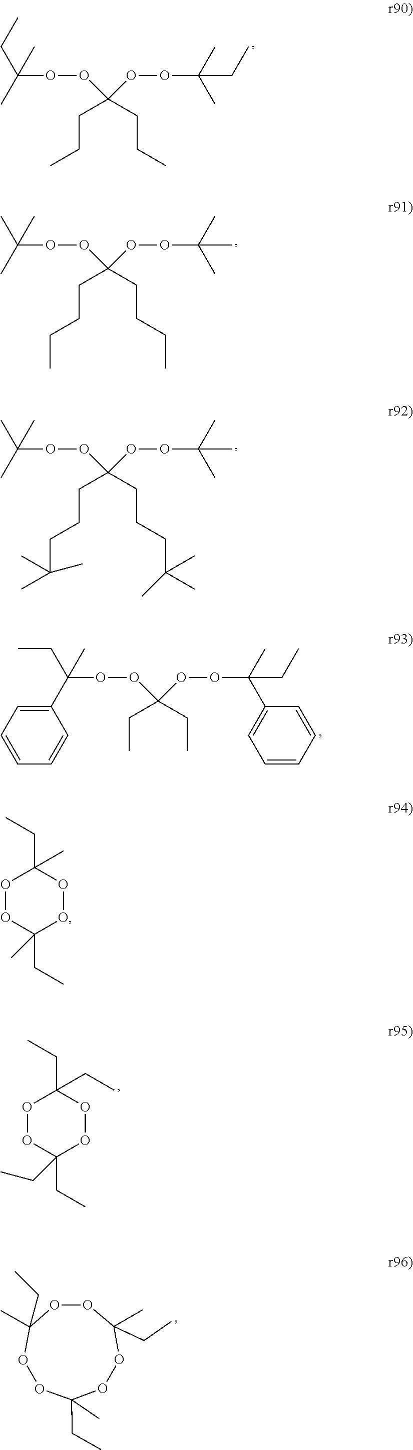

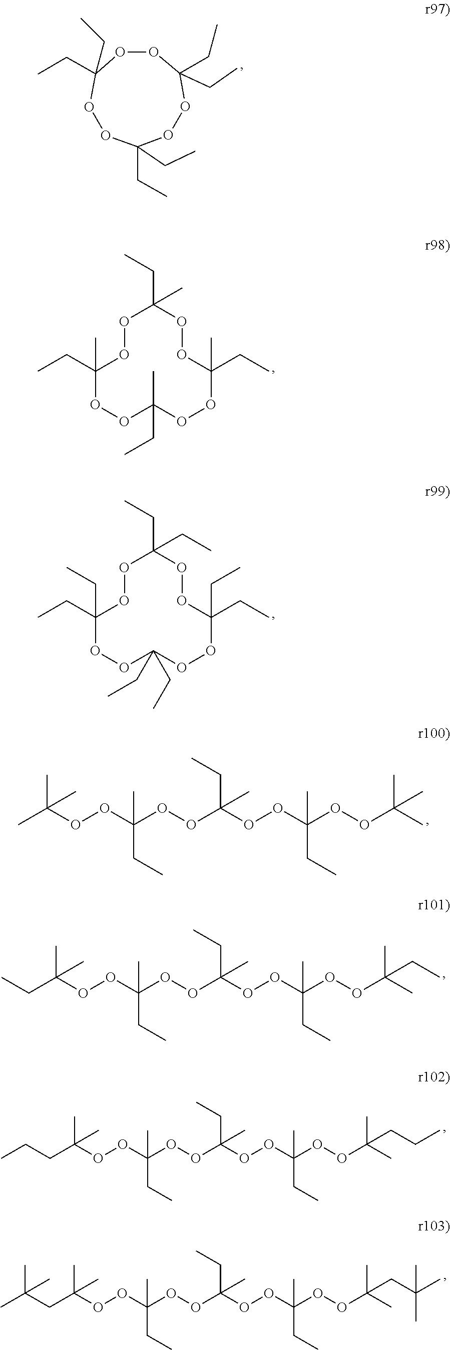

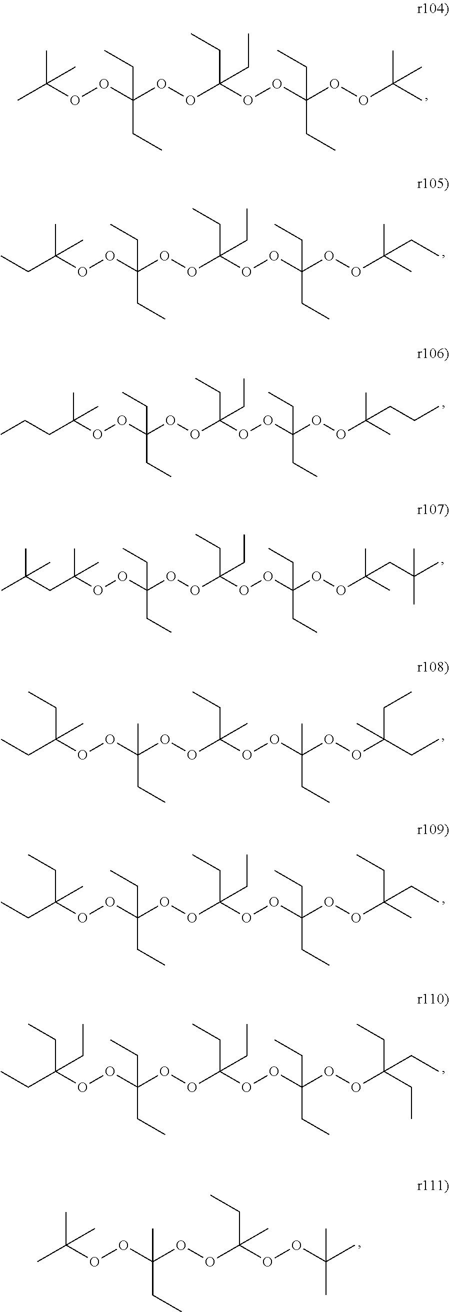

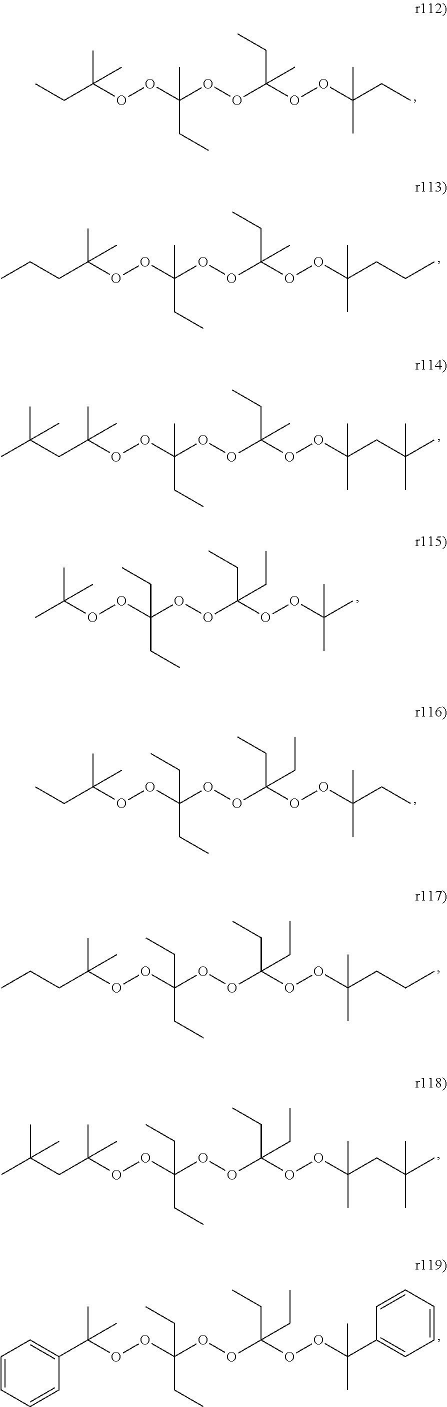

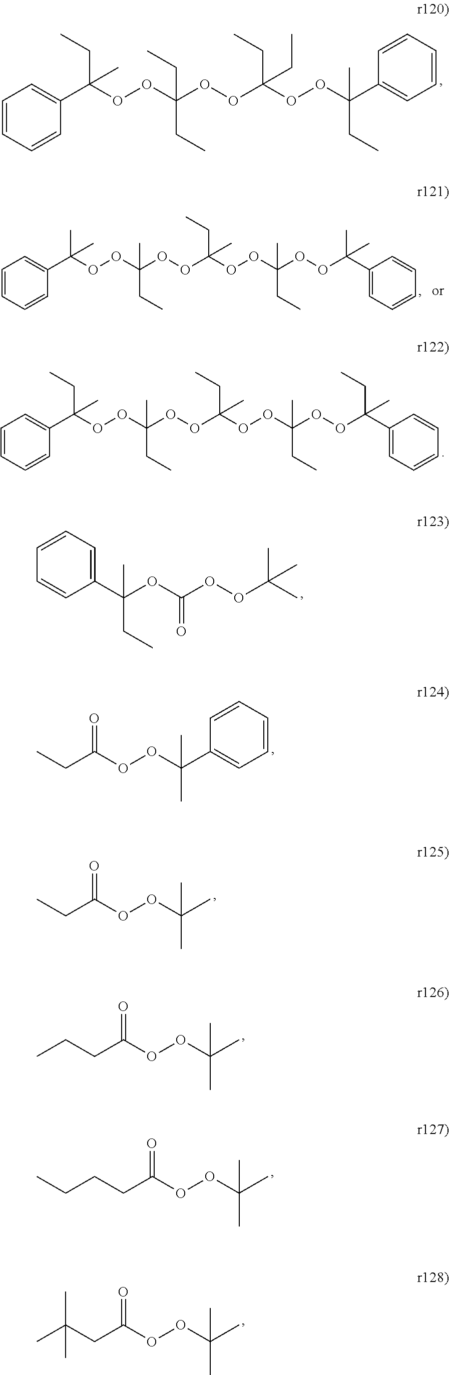

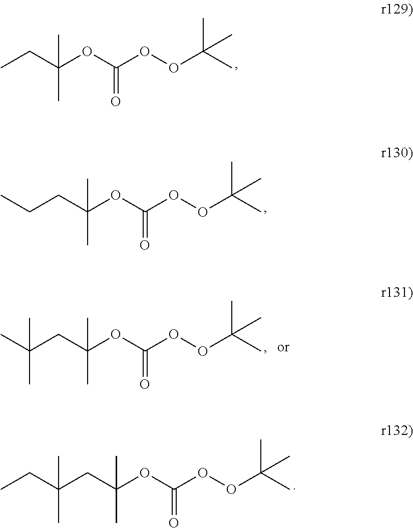

The process of any one of A] or P]-U] above, wherein component b is selected from the following structures r1) through r132):

LA
W] The process of any one of A]-V] above, wherein component a is selected from a telechelic polyolefin of the formula A¹L¹L²A², an unsaturated polyolefin of the formula ALL1, an ethylene/alpha-olefin/nonconjugated polyene interpolymer, or an ethylene/alpha-olefin interpolymer.
X] The process of any one of A]-W] above, wherein the composition is thermally treated, and further heat treated, at a temperature ≥80° C., or ≥90° C., or ≥100° C., or ≥110° C., or ≥120° C., or ≥130° C., or ≥140° C., and/or at a temperature ≤200° ,C., or ≤190° C., or ≤180° C., or ≤170° C., or ≤160° C., or ≤155° C.
Y] A crosslinked composition formed the process of any one of A]-X] above.
A2] A composition comprising at least the following components a) and b):
   a) an olefin-based polymer that comprises a total unsaturation ≥0.20/1000 C;
   b) at least one peroxide selected from at least one of the following:
      i) a peroxide comprising at least one peroxy group comprising an oxyl radical unit selected from Radical I, or
      ii) a peroxide comprising at least one peroxy group comprising an oxyl radical unit selected from Radical II, or
      iii) a peroxide comprising at least one peroxy group comprising an oxyl radical unit selected from Radical III, or
      iv) a peroxide comprising at least one peroxy group comprising an oxyl radical unit selected from Radical IV, or
      v) any combination of i) through iv); and wherein Radical I, Radical II, Radical III or Radical IV are each described above (see A]).
B2] The composition of A2] above, wherein for Radical IV, RI and R2 are each independently CH3, or CH2-Alkyl; and RI and R2 could be same or the different; and at least one of R1 or R2 is CH2-Alkyl.
C2] The composition of A2] above, wherein for Radical IV, R1 and R2 are bonded together to form an aliphatic ring; and where the ring comprises at least one —CH₂— structure adjacent to the quaternary carbon (R1—C(O·)(O·)—R2).
D2] The composition of A2] or C2] above, wherein for Radical IV, the ring structure comprises from 5 to 15 carbon atoms, further from 5 to 9 carbon atoms.
E2] The composition of A2] above, wherein component b is a peroxide comprising at least one peroxy group comprising an oxyl radical unit selected from Radical I. For example, see structures r1)-r68), r76)-r78) above.
F2] The composition of A2] above, wherein component b is a peroxide comprising at least one peroxy group comprising an oxyl radical unit selected from Radical II. For example, see structures r13)-r28), r31), r32), r34)-r44), r123), r129)-r132) above.
G2] The composition of A2] above, wherein component b is a peroxide comprising at least one peroxy group comprising an oxyl radical unit selected from Radical III. For example, see structures r46), r51)-r68), r124)-r128) above.
H2] The composition of any one of A2]-D2] above, wherein component b is a peroxide comprising at least one peroxy group comprising an oxyl radical unit selected from Radical IV. For example, see structures r69)-r93) above.
I2] The composition of any one of A2]-D2] above, wherein component b is a peroxide comprising multiple peroxy groups formed from at least two oxyl radical units independently selected from Radical IV to form a cyclic structure. Further, each radical unit is the same. For example, see r94)-r99) above.
J2] The composition of any one of A2]-D2] or 12] above, wherein component b is a peroxide comprising multiple peroxy groups formed from at least three oxyl radical units independently selected from Radical IV to form a cyclic structure. Further, each radical unit is the same. For example, see r96)-r99) above.
K2] The composition of any one of A2]-D2] above, wherein component b is a peroxide comprising at least two peroxy groups formed from at least two oxyl radical units independently selected from Radical IV to form a non-cyclic structure. Further, each radical unit is the same. For example, see r100)-r122) above.
L2] The composition of any one of A2]-D2] or K2] above, wherein component b is a peroxide comprising at least three peroxy groups formed from at least three oxyl radical units independently selected from Radical IV to form a non-cyclic structure. Further, each radical unit is the same. For example, see r100)-r110, r121), r122) above.
M2] The composition of A2] above, wherein component b is a peroxide comprising at least one peroxy group formed from an oxyl a radical unit selected from Radical I and an oxyl radical unit selected from Radical II. For example, see structures r13)-r28), r31), r32), r34)-r44) above.
N2] The composition of A2] above, wherein component b is a peroxide comprising at least one peroxy group formed from an oxyl a radical unit selected from Radical I and an oxyl radical unit selected from Radical III. For example, see structures r46), r51)-r68) above.
O2] The composition of A2] above, wherein component b is a peroxide comprising at least one peroxy group formed from an oxyl a radical unit selected from Radical I and an oxyl radical unit selected from Radical IV. For example, see structures r70)-r73), r75)-r79), r81)-r-88), r90), r93) above.
P2] The composition of A2] above, wherein component b is selected from the following structures r1) through r132), each as described above (see V]).
Q2] The composition of any one of A2]-P2] above, wherein the peroxide is present in an amount ≥0.10 wt %, or ≥0.20 wt % , or ≥0.30 wt %, or ≥0.40 wt %, or ≥0.50 wt %, or ≥0.52 wt %, or ≥0.54 wt, and/or ≤2.00 wt %, or ≤1.80 wt %, or ≤1.60 wt %, or ≤1.40 wt %, or ≤1.20 wt %, or ≤1.00 wt %, based on the weight of the composition.
R2] The composition of any one of A2]-Q2], wherein the composition comprises ≥50.0 wt %, or ≥60.0 wt %, or ≥70.0 wt %, or ≥80.0 wt %, or ≥85.0 wt %, or ≥90.0 wt %, or ≥95.0 wt %, or ≥98.0 wt %, or ≥99.0 wt %, or ≥99.2 wt %, and/or ≤100.0 wt %, or ≤99.9 wt %, or ≤99.8 wt %, or ≤99.7 wt %, or ≤99.6 wt %, of the sum of components a and b, based on the weight of the composition.
S2] The composition of any one of A2]-R2] above, wherein component a has a total unsaturation ≥0.22/1000 C, or ≥0.24/1000 C, or ≥0.26/1000 C, or ≥0.28/1000 C, or ≥0.30/1000 C, or ≥0.35/1000 C, or ≥0.40/1000 C, or ≥0.45/1000 C, or ≥0.50/1000 C, or ≥0.55/1000 C, or ≥0.60/1000 C, or ≥0.65/1000 C, and/or ≤15.0/1000 C, or ≤10.0/1000 C, or ≤5.00/1000 C, or ≤2.00/1000 C, or ≤1.80/1000 C, or ≤1.60/1000 C, or ≤1.50/1000 C, or ≤1.40/1000 C, or ≤1.30/1000 C, or ≤1.20/1000 C, or ≤1.10/1000 C, or ≤1.00/1000 C.
T2] The composition of any one of A2]-S2] above, wherein component a is an ethylene-based polymer.
U2] The composition of any one of A2]-T2] above, wherein component a has a density ≥0.854, or ≥0.856, or ≥0.858, or ≥0.860, or ≥0.862, or ≥0.864, or ≥0.866, or ≥0.868, or ≥0.870 g/cc, and/or ≤0.960, or ≤0.955, or ≤0.950, or ≤0.945, or ≤0.940, or ≤0.935, or ≤0.930, or ≤0.925, or ≤0.920, or ≤0.915, or ≤0.910, or ≤0.905, or ≤0.900, or ≤0.895, or ≤0.890, or ≤0.885, or ≤0.880, or ≤0.878, or ≤0.876, or ≤0.875, or ≤0.874 g/cc.
V2] The composition of any one of A2]-U2] above, wherein component a has a melt index (12) ≥0.1, or ≥0.2, or ≥0.5, or ≥1.0, or ≥2.0, or ≥5.0, or ≥8.0, or ≥10, or ≥15, or ≥20, or ≥25 dg/min, and/or ≤2000, or ≤1000, or ≤500, or ≤200, or ≤100, or ≤50, or ≤40, or ≤30 dg/min.
W2] The composition of any one of A2]-V2] above, wherein component a is selected from a telechelic polyolefin of the formula A¹L¹L²A², an unsaturated polyolefin of the formula A¹L¹, an ethylene/alpha-olefin/nonconjugated polyene interpolymer, or an ethylene/alpha-olefin interpolymer.
X2] The composition of any one of A2]-W2] above, wherein the composition is thermally treated, and further heat treated, at a temperature ≥80° C., or ≥90° C., or ≥100° C., or ≥110° C., or ≥120° C., or ≥130° C., or ≥140° C., and/or at a temperature ≤200° C., or ≤190° C., or ≤180° C., or ≤170° C., or ≤160° C., or ≤155° C.
Y2] A crosslinked composition formed the composition of any one of A2]-X2] above.
A3] The process of any one of A]-X] above, or the composition of any one of Y]-Y2] above, wherein component a is a telechelic polyolefin of the formula A¹L¹L²A²; wherein L¹ is an ethylene-based polymer, further an ethylene/alpha-olefin interpolymer, and further an ethylene/alpha-olefin copolymer.
B3] The process of A3] above, or the composition of A3] above, wherein the alpha-olefin is a C₃-C₂₀ alpha-olefin, further a C₃-C₁₀ alpha-olefin, and further propylene, 1-butene, 1-hexene or 1-octene, further propylene, 1-butene or 1-octene, further 1-butene or 1-octene, further 1-octene.
C3] The process of A3] or B3] above, or the composition of A3] or B3] above, wherein the telechelic polyolefin of the formula A¹L¹L²A² has a melt index (I2) ≥0.1, or ≥0.2, or ≥0.5, or ≥1.0, or ≥5.0, or ≥10, or ≥15, or ≥20, or ≥25 dg/min, and/or ≤2000, or ≤1000, or ≤500, or ≤200, or ≤100, or ≤50, or ≤45, or ≤40, or ≤35, or ≤30 dg/min.
D3] The process of any one of A]-X] above, or the composition of any one of Y]-Y2] above, wherein component a is an unsaturated polyolefin of the formula A¹L¹; wherein L¹ is an ethylene-based polymer, further an ethylene/alpha-olefin interpolymer, and further an ethylene/alpha-olefin copolymer.
E3] The process of D3] above, or the composition of D3] above, wherein the alpha-olefin is a C₃-C₂₀ alpha-olefin, further a C₃-C₁₀ alpha-olefin, and further propylene, 1-butene, 1-hexene or 1-octene, further propylene, 1-butene or 1-octene, further 1-butene or 1-octene, further 1-octene.
F3] The process of D3] or E3] above, or the composition of D3] or E3] above, wherein the unsaturated polyolefin of the formula A¹L¹ has a melt index (I2) ≥0.1, or ≥0.2, or ≥0.6, or ≥0.8, or ≥0.9, or ≥1.0, or ≥1.1, or ≥1.2, or ≥1.4, or ≥1.6, or ≥1.8, or ≥2.0, or ≥5.0, or ≥8.0, or ≥10, or ≥12 dg/min, and/or ≤2000, or ≤1000, or ≤500, or ≤200, or ≤100, or ≤50, or ≤45, or ≤35, or ≤30 dg/min.
G3] The process of any one of A]-X] above, or the composition of any one of Y]-Y2] above, wherein component a is an ethylene/alpha-olefin/non-conjugated polyene interpolymer, further an ethylene/alpha-olefin/nonconjugated diene interpolymer, and further an ethylene/alpha-olefin/nonconjugated diene terpolymer, further an EPDM.
H3] The process of G3] above, or the composition of G3] above, wherein the ethylene/alpha-olefin/nonconjugated polyene interpolymer has a Mooney Viscosity (ML 1+4, 125° C.) ≥2.0, or ≥5.0, or ≥10, or ≥12, or ≥14, or ≥16, or ≥18, and/or ≤60, or ≤55, or ≤50, or ≤45, or ≤40, or ≤35, or ≤30, or ≤25, or ≤22 dg/min.
I3] The process of any one of A]-X] above, or the composition of any one of Y]-Y2] above, wherein component a is an ethylene/alpha-olefin interpolymer, and further an ethylene/alpha-olefin copolymer.
J3] The process of I3] above, or the composition of I3] above, wherein the alpha-olefin is a C₃-C₂₀ alpha-olefin, further a C₃-C₁₀ alpha-olefin, and further propylene, 1-butene, 1-hexene or 1-octene, further propylene, 1-butene or 1-octene, further 1-butene or 1-octene, further 1-octene.
K3] The process of I3] or J3] above, or the composition of I3] or J3] above, wherein the ethylene/alpha-olefin interpolymer has a melt index (I2) ≥0.1, or ≥0.2, or ≥of 0.5, or ≥1.0, or ≥2.0, or ≥4.0 dg/min, and/or ≤2000, or ≤1000, or ≤500, or ≤200, or ≤100, or ≤50, or ≤40, or ≤35 dg/min.
L3] The process of any one of A]-X] or A3]-K3] above, or the composition of any one of Y]-Y2] or A3]-K3] above, wherein component a has a molecular weight distribution MWD (=Mw/Mn) ≥1.80, or ≥1.90, or ≥2.00, or ≥2.10, or ≥2.15, or ≥2.20, or ≥2.25, or ≥2.30, or ≥2.35, or ≥2.40, and/or ≤5.00, or ≤4.80, or ≤4.60, or ≤4.40, or ≤4.20 or ≤4.00, or ≤3.80, or ≤3.60, or ≤3.40 or ≤3.20, or ≤3.00.
M3] The process of any one of A]-X] or A3]-L3] above, or the composition of any one of Y]-Y2] or A3]-L3] above, wherein component a has a number average molecular weight Mn ≥5,000, or ≥6,000, or ≥8,000, or ≥10,000, or ≥12,000, or ≥14,000, or ≥16,000, or ≥18,000, or ≥20,000 g/mol, and/or ≤120,000, or ≤100,000, or ≤80,000, or ≤60,000, or ≤55,000, or ≤50,000, or ≤45,000, or ≤40,000, or ≤35,000 g/mol.
N3] The process of any one of A]-X] or A3]-M3] above, or the composition of any one of Y]-Y2] or A3]-M3] above, wherein component a has a V0.1 (at 190° C.) ≥10 Pa·s, or ≥50 Pa·s, or ≥100 Pas or ≥200 Pa·s, or ≥500 Pa·s, or ≥800 Pa·s, or ≥1000 Pa·s, or ≥1200 Pa·s, or ≥1400 Pa·s, or ≥1500 Pa·s, and/or ≤100,000 Pa·s, or ≤50,000 Pa·s, or ≤20,000 Pa·s, or ≤10,000 Pa·s, or ≤9,000 Pa·s, or ≤8,000 Pa·s, or ≤7,000 Pa·s, or ≤6,000 Pa·s. See DMS test method, incorporated herein by reference, in WO2020/140067.
O3] The process of any one of A]-X] or A3]-N3] above, or the composition of any one of Y]-Y2] or A3]-N3] above, wherein component a has a rheology ratio (RR=V0.1/V100, each at 190° C.) ≥1.0, or ≥1.5, or ≥1.6, or ≥1.7, or ≥1.8, or ≥1.9, or ≥2.0, or ≥2.1, and/or ≤20, or ≤15, or ≤10, or ≤8.0, or ≤6.0, or ≤5.5, or ≤5.2, or ≤5.0, or ≤4.8, or ≤4.6, or ≤4.5. See DMS test method noted above.
P3] The process of any one of A]-X] or A3]-O3] above, or the composition of any one of Y]-Y2] or A3]-O3] above, wherein component a has a tan delta (0.1 rad/s, 190° C.) ≥3.0, or ≥3.5, or ≥4.0, or ≥4.5, or ≥5.0, or ≥5.5, or ≥6.0, or ≥7.0, or ≥8.0, or ≥9.0, or ≥10, and/or ≤70, or ≤65, or ≤60, or ≤55. See DMS test method noted above.
Q3] The process of any one of A]-X] or A3]-P3] above, or the composition of any one of Y]-Y2] or A3]-P3] above wherein component a has a % vinyl ≥2.0%, or ≥4.0%, or ≥6.0%, or ≥8.0%, or ≥10%, or ≥15%, or ≥20%, or ≥25%, or ≥30%, or ≥35%, or ≥40%, or ≥45%, or ≥50%, and/or ≤90%, or ≤85%, or ≤80%, or ≤75%, or ≤70%, or ≤65%, where % vinyl=[(vinyl/1000 C)/(total unsaturation/1000 C)]×100.
R3] The process of any one of A]-X] or A3]-Q3] above, or the composition of any one of Y]-Y2] or A3]-Q3] above wherein component a has a vinyl content ≥0.02/1000 C, or ≥0.05/1000 C, or ≥0.10/1000 C, or ≥0.20/1000 C, or ≥0.23/1000 C, or ≥0.26/1000 C, or ≥0.28/1000 C, or ≥0.30/1000 C, or ≥0.32/1000 C, or ≥0.34/1000 C, or ≥0.36/1000 C, and/or ≤0.80/1000 C, or ≤0.75/1000 C, or ≤0.70/1000 C, or ≤0.65/1000 C, or ≤0.62/1000 C, or ≤0.65/1000 C.
S3] The process of any one of A]-X] or A3]-R3] above, or the composition of any one of Y]-Y2] or A3]-R3] above, wherein component a has a sum of vinyl and vinylidene content ≥0.08/1000 C, or ≥0.10/1000 C, or ≥0.20/1000 C, or ≥0.30/1000 C, or ≥0.40/1000 C, or ≥0.42/1000 C, or ≥0.44/1000 C, or ≥0.46/1000 C, or ≥0.48/1000 C, or ≥0.50/1000 C, or ≥0.52/1000 C, and/or ≤1.00/1000 C, or ≤0.95/1000 C, or ≤0.90/1000 C, or ≤0.85/1000 C.
T3] The process of any one of A]-X] or A3]-S3] above, or the composition of any one of Y]-Y2] or A3]-S3] above, wherein component a has a % vinylidene ≥2.0%, or ≥4.0%, or ≥6.0%, or ≥8.0%, or ≥10%, or ≥15%, or ≥17%, or ≥20%, or ≥22%, or ≥24%, and/or ≤60%, or ≤58%, or ≤56%, or ≤54%, or ≤52%, or ≤50%, or ≤48%, or ≤46%, or ≤44%, where % vinylidene=[(vinylidene/1000 C)/(total unsaturation/1000 C)]×100.
U3] The process of any one of A]-X] or A3]-T3] above, or the composition of any one of Y]-Y2] or A3]-T3] above wherein component a has a vinylidene content ≥0.02/1000 C, or ≥0.04/1000 C, or ≥0.06/1000 C, or ≥0.08/1000 C, or ≥0.10/1000 C, and/or ≤0.38/1000 C, or ≤0.36/1000 C, or ≤0.34/1000 C, or ≤0.32/1000 C, or ≤0.30/1000 C, or ≤0.29/1000 C, or ≤0.25/1000 C.
V3] The process of any one of A]-X] or A3]-U3] above, or the composition of any one of Y]-Y2] or A3]-U3] above, wherein component a has a % vinylene ≥0.20%, or ≥0.40%, or ≥0.60%, or ≥0.80%, or ≥1.0%, or ≥1.5%, or ≥2.0%, or ≥3.0%, or ≥4.0%, or ≥5.0%, or ≥6.0%, or ≥7.0%, or ≥8.0%, or ≥9.0%, or ≥10%, and/or ≤50%, or ≤45%, or ≤40%, or ≤35%, or ≤30%, or ≤25%, or ≤22%, or ≤20%, or ≤18%, or ≤15% where %vinylene =[(vinylene/1000 C)/(total unsaturation/1000 C)]×100.
W3] The process of any one of A]-X] or A3]-V3] above, or the composition of any one of Y]-Y2] or A3]-V3] above, wherein component a has a % trisubstituted ≥0.10%, or ≥0.15%, or ≥0.20%, or ≥0.25%, or ≥0.30%, or ≥0.40%, or ≥0.50%, or ≥0.60%, or ≥0.70%, or ≥0.80%, or ≥0.90%, or ≥1.0%, or ≥1.1%, or ≥1.2%, or ≥1.3%, or ≥1.4%, and/or ≤25%, or ≤20%, or ≤10%, or ≤9.0%, or ≤8.0%, or ≤7.0%, or ≤6.0%, or ≤5.8%, or ≤5.6%, where % trisubstituted=[(trisubstituted/1000 C)/(total unsaturation/1000 C)]×100.
X3] The process of any one of A]-X] or A3]-W3] above, or the composition of any one of Y]-Y2] or A3]-W3] above, wherein the composition comprises ≥90.0 wt %, or ≥92.0 wt %, or ≥94.0 wt %, or ≥96.0 wt %, or ≥98.0 wt % or ≥98.1 wt %, or ≥98.2 wt %, or ≥98.3 wt %, or ≥98.4 wt %, or ≥98.5 wt % and/or ≤100.0 wt %, or ≤99.9 wt %, or ≤99.8 wt %, or ≤99.7 wt %, or ≤99.6 wt %, or ≤99.5 wt % of component a based on the weight of the composition.
Y3] The process of any one of A]-X] or A3]-X3] above, or the composition of any one of Y]-Y2] or A3]-X3] above, wherein the weight ratio of component a to component b is ≥50, or ≥60, or ≥70, or ≥80, or ≥90, or ≥100 and/or ≤200, or ≤190, or ≤180, or ≤170, or ≤160, or ≤150, or ≤145, or ≤140, or ≤135, or ≤130.
Z3] The process of any one of A]-X] or A3]-Y3] above, or the composition of any one of Y]-Y2] or A3]-Y3] above, wherein the composition comprises a crosslinking coagent (component c).
A4] The process of Z3] above, or the composition of Z3] above, wherein component c is present in an amount ≥0.10 wt %, or ≥0.20 wt %, or ≥0.30 wt %, or ≥0.40 wt %, or ≥0.50 wt % and/or ≤1.0 wt %, or ≤0.95 wt %, or ≤0.90 wt %, or ≤0.85 wt %, or ≤0.80 wt %, based on the weight of the composition.
B4] The process of Z3] or A4] above, or the composition of any one of Z3] or A4] above, wherein the weight ratio of component b to component c is ≥0.50, or ≥0.60, or ≥0.70, or ≥0.80, or ≥0.90, or ≥1.0, or ≥1.1, and/or ≤5.0, or ≤4.5, or ≤4.0, or ≤3.5, or ≤3.0, or ≤2.5, or ≤2.0, or ≤1.9, or ≤1.8, or ≤1.7, or ≤1.6.
C4] The process of any one of A]-X] or A3]-B4] above, or the composition of any one of Y]-Y2] or A3]-B4] above, wherein the composition further comprises at least an additive.
D4] The process of any one of A]-X] or A3]-C4] above, or the composition of any one of Y]-Y2], or A3]-C4] above, wherein the composition further comprises a polymer, different from component a in one or more features, such as comonomer type, comonomer content, Mn, Mw, MWD, V0.1, V100 or RR.
E41 The process of any one of A]-X] or A3]-D4] above, or the composition of any one of Y]-Y2] or A3]-D4] above, wherein the composition comprises ≤10 ppm, or ≤5.0 ppm, or ≤2.0 ppm, or ≤1.0 ppm, or ≤0.5 ppm of a silane coupling agent, based on the weight of the composition; and further the composition does not comprise a silane coupling agent.
F4] The process of any one of A]-X] or A3]-E4] above, or the composition of any one of Y]-Y2] or A3]-E4] above, wherein the composition has a percent change (Δ) in T90 ≥−80%, or ≥−70%, or ≥−65%, or ≥−60%, or ≥−55%, or ≥−50%, or ≥−45%, or ≥−40%, and/or ≤−10%, or ≤−15%, ≤−20%, or ≤−25%, or ≤−30%, as compared to as comparative composition, similar to the composition, except the comparative composition contains TBEC (tert-butylperoxy-2-ethylhexyl carbonate) as the peroxide; and wherein the % Δ in T90=[(T90_{comp}−T90_{TBEC})/(T90_{TBEC})]×100; where T90_{comp} is the T90 value of the composition, and the T90_{TBEC} value is the T90 of the comparative composition. The T90 values are determined in accordance with the MDR test described below.
G4] The process of any one of A]-X] or A3]-F4] above, or the composition of any one of Y]-Y2] or A3]-F4] above, wherein the composition has a percent change (Δ) in MH ≥−40%, or ≥−35%, or ≥−30%, or ≥−25%, ≥−20%, or ≥−15%, or ≥−10%, or ≥−5.0%, or ≥0%, or ≥2.0%, or ≥4.0%, or ≥6.0%, or ≥8.0%, or ≥10%, or ≥20%, or ≥30%, and/or ≤400%, or ≤350%, or ≤300%, or ≤250%, or ≤200%, or ≤150%, or ≤100%, or ≤90%, or ≤80%, or ≤70%, or ≤60%, or ≤50%, or ≤40%, as compared to as comparative composition, similar to the composition, except the comparative composition contains TBEC as the peroxide; and wherein the % Δ in MH=[(MH_{comp}−MH_{TBEC})/(MH_{TBEC})]×100; where MH_{comp} is the MH value of the composition, and the MH_{TBEC} value is the MH of the comparative composition. The MH values are determined in accordance with the MDR test described below.
H4] The process of any one of A]-X] or A3]-G4] above, or the composition of any one of Y]-Y2] or A3]-G4] above, wherein the composition has a percent change (Δ) in MH ≥2.0%, or ≥5.0%, or ≥10%, or ≥20%, or ≥30%, or ≥40%, or ≥50%, or ≥60%, or ≥80%, or ≥100%, and/or ≤400%, or ≤350%, or ≤300%, or ≤250%, or ≤200%, as compared to as comparative composition, similar to the composition, except the comparative composition contains TBEC as the peroxide; and wherein the % Δ in MH=[(MH_{comp}−MH_{TBEC})/(MH_{TBEC})]×100; where MH_{comp} is the MH value of the composition, and the MH_{TBEC} value is the MH of the comparative composition. The MH values are determined in accordance with the MDR test described below.
I4] The process of any one of A]-X] or A3]-H4] above, or the composition of any one of Y]-Y2] or A3]-H4] above, wherein the composition has a [Mn×(Total Unsat/1000 C)] value ≥4.0, or ≥4.5, or ≥5.0, or ≥5.5, ≥6.0, or ≥6.5, or ≥7.0, or ≥8.0, or ≥8.5, and/or ≤50, or ≤45, or ≤43, or ≤40, or ≤35, or ≤30, or ≤28, or ≤26, or ≤24, or ≤22 kg/mol.
J4] The process of any one of A]-X] or A3]-14] above, or the composition of any one of Y]-Y2] or A3]-[4] above, wherein the composition is crosslinked by the application of heat only.
K4] The process of any one of A]-X] or A3]-14] above, or the composition of any one of Y]-Y2] or A3]-[4] above, wherein the composition is crosslinked by the application of heat and radiation.
L4] An article comprising at least one component formed from the composition of any one of Y]-Y2] or A3]-K4] above.
M4] The article of L4] above, wherein the article is a film, or a foam, and further a film.
N4] The article of L4] above, wherein the article is a solar cell module, a wire or cable, a footwear component, an automotive part, a window profile, a tire, a tube/hose, or a roofing membrane, and further a solar cell module, a wire or cable, a footwear component, an automotive part, and further a solar cell module.
O4] The article of L4] above, wherein the article is an encapsulation film for a solar cell module.
P4] The article of L4] above, wherein the article is a solar cell module comprising a front transparent surface protective layer, a front crosslinked encapsulation film, a solar cell element, a back crosslinked encapsulation film, and a back transparent surface protective layer.
Q4] A lamination process to prepare a solar cell module, said process comprising crosslinking a film formed from the composition of any one of A2]-X2] or A3]-K4] above.
R4] A process to form a crosslinked composition, said process comprising thermally treating the composition of any one of A2]-X2] or A3]-K4] above.
S4] A crosslinked composition formed from the process of any one of A]-X] or A3]-K4] above.

### TEST METHODS

### Moving Die Rheometer (MDR) Test

Cure characteristics were measured using an Alpha Technologies Moving Die Rheometer (MDR) 2000, according to ASTM D5289, with a 0.5 deg arc on the pellets, which were stored for 24 hours at RT (room temp.) in bottle after soaking. For each composition, the MDR was loaded with approximately 4.5 g of pellets. The MDR was run for 25 minutes at 150° C. or 200° C., and the “time versus torque” profile was generated over the given interval. The following data were used from each MDR run: MH (dNm), or the maximum torque exerted by the MDR during the 25 minute testing interval (this usually corresponds to the torque exerted at 25-minute time point); ML (dNm), or the minimum torque exerted by the MDR during the 25 minute testing interval (this usually corresponds to the torque exerted at the beginning of the test interval); and T90 (time it takes to reach 90% of the (MH-ML) value).

### ¹H NMR Method

Sample Preparation: Each sample was prepared by adding approximately 130 mg of sample to 3.25 g of a “50/50 by weight tetrachlorethane-d2/perchloroethylene (TCE-d2/PCE) with 0.001M Cr(AcAc)₃, ” in a NORELL 1001-7, 10 mm, NMR tube. The sample was purged by bubbling N₂ through the solvent, via a pipette inserted into the tube, for approximately five minutes to prevent oxidation. The tube was then capped and sealed with TEFLON tape, before heating and vortex mixing at 115° C. to achieve a homogeneous solution.

Data Acquisition Parameters and Data Analysis: ¹H NMR was performed on a Bruker AVANCE 600 MHz spectrometer, equipped with a Bruker high-temperature CryoProbe, with a sample temperature of 120° C. Two experiments were run to obtain spectra, a control spectrum to quantitate the total polymer protons, and a double presaturation experiment, which suppresses the intense peaks associated with the polymer chains, and enables high sensitivity spectra for quantitation of the end-groups. The control was run with ZG pulse, 16 scans, AQ 1.82s, D₁ (relaxation delay) 14 s. The double presaturation experiment was run with a modified pulse sequence, lc1prf2.zz, 64 scans, AQ 1.82 s, D₁ (presaturation time) 2 s, D13 (relaxation delay) 12 s. Unsaturation measurements were made according to the following method. The area under the resonance from the polymer chains (i.e., CH, CH₂, and CH₃ in the polymers) was measured from the spectrum acquired during first experiment (the control spectrum), described above.

The unsaturation was analyzed with the method in Reference 3 noted below.
Reference 1: Z. Zhou, R. Kuemmerle, J. C. Stevens, D. Redwine, Y. He, X. Qiu, R. Cong, J. Klosin, N. Montañez, G. Roof, Journal of Magnetic Resonance, 2009, 200, 328.
Reference 2: Z. Zhou, R. Kümmerle, X. Qiu, D. Redwine, R. Cong, A. Taha, D. Baugh, B. Winniford, Journal of Magnetic Resonance: 187 (2007) 225. Reference 3: Z. Zhou, R. Cong, Y. He, M. Paradkar, M. Demirors, M. Cheatham, W. deGroot, Macromolecular Symposia, 2012, 312, 88.

The peak areas for each type of observed unsaturation (i.e., vinyl, vinylidene, vinylene, trisubstituted, cyclohexene, and ethylidene norbornene (ENB) endo and exo isomers from EPDM unsaturation) was measured from the spectrum acquired during the second (presaturation) experiment described above. In the case of EPDM spectra, overlapping peak areas are compensated appropriately. Both spectra were normalized to the solvent peak area. Moles of respective unsaturation were calculated by dividing the area under the unsaturation resonance by the number of protons contributing to that resonance.

Moles of carbons in the polymers were calculated by dividing the area under the peaks for polymer chains (i.e., CH, CH₂, and CH₃ in the polymers) by two. The amount of total unsaturation (sum of the above unsaturations) was then expressed as a relative ratio of moles of total unsaturation to the moles of carbons in the polymers, with expression of the number of unsaturation per 1000 Carbon (per 1000 C). Note that the results for EPDM samples in

TCE-d2/PCE can be calculated from spectra acquired using 1,4-orthodichlorobenzene-d4/PCE, to eliminate the TCE peak interference with the single vinyl proton at about 5.9 ppm. Results are the same within <5% relative.

### Mooney Viscosity of Polymer (No Oil, no Filler)

Mooney Viscosity (ML 1+4 at 125° C.) is measured in accordance with ASTM 1646, with a one minute preheat time and a “four minute” rotor operation time. The instrument is an Alpha Technologies Mooney Viscometer 2000. Sample size around 25 grams.

### Melt Index

The melt index 12 (or MI) of an ethylene-based polymer is measured in accordance with ASTM D-1238, condition 190° C./2.16 kg. The melt flow rate MFR of a propylene-based polymer is measured in accordance with ASTM D-1238, condition 230° C./2.16 kg.

### Polymer Density

ASTM D4703 was used to make a polymer plaque for density analysis. ASTM D792, Method B, was used to measure the density of each polymer.

### Gel Test

Lamination: A plaque of each composition, with dimensions 3 cm×3 cm×0.5 mm (thickness) (nine pieces in one mold), was prepared by compression molding at 100° C. (two minutes pre-heating and two minutes under a pressure of 10MPa). Each plaque was cured during lamination, on a SHUNHONG SH-X-1000 laminator. Each plaque (3 cm×3 cm×0.5 mm) was placed on a PTFE film (0.15 mm thick), which, in turn, was placed on a glass substrate (3 mm thick) within a metal frame (3 cm×3 cm×0.5 mm) (nine pieces in one mold), and another PTFE film (0.15 mm thick) was placed on top of the plaque. Lamination was conducted at 150° C., using a two-step method as follows: 1) a 4 minute of preheat (at 150° C.) under vacuum without pressure; and 2) a cure for 4, 6, 8, 10 or 12 minutes, at 150° C., with 1 bar pressure. Thus, the total lamination time was 8 (4+4) minutes, 10 (4+6) minutes, 12 (4+8) minutes, 14 (4+10) minutes, or 16 (4+12) minutes.

The cured plaque prepared from the lamination process was cut into small pieces, 3 mm×3 mm. Then around 0.5 g of sample (Ws) was sealed in a metal mesh (mesh number is 120), to form a packed sample, and the packed sample was weighed (Wt1). The packed sample was put into a glass bottle (250 ml), containing xylene (100 ml) for 24 hours. Then the packed sample was transferred to a flask (500 ml), equipped with condenser, and containing 350 ml xylene. After refluxing for 5 hours, the packed samples was removed from xylene, and put into vacuum oven, and heated at 120° C., for 2 hours, under vacuum condition. After which time, the packed sample was removed from the oven, and weighed (Wt2). Gel content=(Wt2−Wt1)/Ws*100%.

### Gel Permeation Chromatography—Ethylene-Based Polymers

The chromatographic system consists of a PolymerChar GPC-IR (Valencia, Spain) high temperature GPC chromatograph, equipped with an internal infra-red detector (IR5). The autosampler oven compartment is set at 160° C., and the column compartment is set at 150° C. The columns are four AGILENT “Mixed A” 30 cm, 20-micron linear mixed-bed columns. The chromatographic solvent is 1,2,4-trichlorobenzene, which contains 200 ppm of butylated hydroxytoluene (BHT). The solvent source is nitrogen sparged. The injection volume is 200 microliters, and the flow rate is 1.0 milliliters/minute.

Calibration of the GPC column set is performed with 21 narrow molecular weight distribution polystyrene standards, with molecular weights ranging from 580 to 8,400,000 g/mol, and which are arranged in six “cocktail” mixtures, with at least a decade of separation between individual molecular weights. The standards are purchased from Agilent Technologies. The polystyrene standards are prepared at “0.025 grams in 50 milliliters” of solvent, for molecular weights equal to, or greater than, 1,000,000, and at “0.05 grams in 50 milliliters” of solvent, for molecular weights less than 1,000,000. The polystyrene standards are dissolved at 80° C., with gentle agitation, for 30 minutes. The polystyrene standard peak molecular weights are converted to polyethylene molecular weights using Equation 1 (as described in Williams and Ward, J. Polym. Sci., Polym. Let., 6, 621 (1968)):

M_{polyethylene}=A×(M_{polystyrene})^{B} (EQ1),

where M is the molecular weight, A has a value of 0.4315 and B is equal to 1.0.

A fifth order polynomial is used to fit the respective polyethylene-equivalent calibration points. A small adjustment to A (from approximately 0.375 to 0.445) is made to correct for column resolution and band-broadening effects, such that linear homopolymer polyethylene standard is obtained at 120,000 Mw.

The total plate count of the GPC column set is performed with decane (prepared at “0.04 g in 50 milliliters” of TCB, and dissolved for 20 minutes with gentle agitation.) The plate count (Equation 2) and symmetry (Equation 3) are measured on a 200 microliter injection according to the following equations:

$$Plate Count = 5.54 * {( \frac{( {RV}_{Peak Max}}{Peak Width at \frac{1}{2} height} )}^{2} , \qquad ( EQ2 )$$

where RV is the retention volume in milliliters, the peak width is in milliliters, the peak max is the maximum height of the peak, and ½ height is ½ height of the peak maximum; and

$$Symmetry = \frac{? Rear Peak {RV}_{one tenth height} - {RV}_{Peak max} ?}{? {RV}_{Peak max} - Front Peak {RV}_{one tenth height} ?} , \qquad ( EQ3 )$$

where RV is the retention volume in milliliters, and the peak width is in milliliters, Peak max is the maximum position of the peak, one tenth height is 1/10 height of the peak maximum, and where rear peak refers to the peak tail at later retention volumes than the peak max, and where front peak refers to the peak front at earlier retention volumes than the peak max. The plate count for the chromatographic system should be greater than 18,000, and symmetry should be between 0.98 and 1.22.

Samples are prepared in a semi-automatic manner with the PolymerChar “Instrument Control” Software, wherein the samples are weight-targeted at “2 mg/ml,” and the solvent (contains 200 ppm BHT) is added to a pre nitrogen-sparged, septa-capped vial, via the PolymerChar high temperature autosampler. The samples are dissolved for two hours at 160° C. under “low speed” shaking.

The calculations of Mn_{(GPC)}, MW_{(GPC)}, and MZ_{(GPC)} are based on GPC results using the internal IR5 detector (measurement channel) of the PolymerChar GPC-IR chromatograph according to Equations 4-6, using PolymerChar GPCOne™ software, the baseline-subtracted IR chromatogram at each equally-spaced data collection point (i), and the polyethylene equivalent molecular weight obtained from the narrow standard calibration curve for the point (i) from Equation 1. Equations 4-6 are as follows:

$$\begin{matrix}{Mn}_{( GPC )} = \frac{{\sum }^{i} {IR}_{i}}{{\sum }^{i} ( {IR}_{i} / {M}_{{polyethylene}_{i}} )} , & ( EQ 4 ) \\ {Mw}_{( GPC )} = \frac{{\sum }^{i} ( {IR}_{i} / {M}_{{polyethylene}_{i}} )}{{\sum }^{i} {IR}_{i}} , and & ( EQ 5 ) \\ {Mz}_{( GPC )} = \frac{{\sum }^{i} ( {IR}_{i} * {M}_{{polyethylene}_{i}}^{2} )}{{\sum }^{i} ( {IR}_{i} / {M}_{{polyethylene}_{i}} )} . & ( EQ 6 )\end{matrix}$$

In order to monitor the deviations over time, a flowrate marker (decane) is introduced into each sample, via a micropump controlled with the PolymerChar GPC-IR system. This flowrate marker (FM) is used to linearly correct the pump flowrate (Flowrate(nominal)) for each sample, by RV alignment of the respective decane peak within the sample (RV(FM Sample)), to that of the decane peak within the narrow standards calibration (RV(FM Calibrated)). Any changes in the time of the decane marker peak are then assumed to be related to a linear-shift in flowrate (Flowrate(effective)) for the entire run. To facilitate the highest accuracy of a RV measurement of the flow marker peak, a least-squares fitting routine is used to fit the peak of the flow marker concentration chromatogram to a quadratic equation. The first derivative of the quadratic equation is then used to solve for the true peak position. After calibrating the system, based on a flow marker peak, the effective flowrate (with respect to the narrow standards calibration) is calculated as Equation 7:

Flowrate(effective)=Flowrate(nominal)*(RV(FM Calibrated)/RV(FM Sample)) (EQ7).

Processing of the flow marker peak is done via the PolymerChar GPCOne™ Software. Acceptable flowrate correction is such that the effective flowrate is within +/−0.7% of the nominal flowrate.

### EXPERIMENTAL

### Commercial Polymers and Additives

Commercial polymers and additives are listed below. A summary of the olefin-based polymers used in the studies below are listed in Tables 1A through 1C.

NORDEL 3720P EPDM, Mooney viscosity=20 (ML 1+4, 125° C.), 0.5 wt % ENB, 69.5 wt % ethylene, available from The Dow Chemical Company. NORDEL 3722P EPDM, Mooney viscosity=18 (ML 1+4, 125° C.), 0.5 wt % ENB, 70.5 wt % ethylene, available from The Dow Chemical Company.

ENGAGE PV 8669 Polyolefin Elastomer (POE), density=0.873 g/cc, I2=14 dg/min, available from The Dow Chemical Company. XUS38661.00 Experimental Polyolefin Elastomer (POE), ethylene/1-octene copolymer: density=0.8770-0.8830 g/cc, I2=14-22 dg/min, available from The Dow Chemical Company. ENGAGE 8407 Polyolefin Elastomer (POE), ethylene/1-octene copolymer: density=0.870 g/cc, I2=30 dg/min, available from The Dow Chemical Company. EVA E282PV (ethylene vinyl acetate copolymer), density=0.948 g/cc, I2=25 dg/min, VA content 28 wt %, available from Hanwha.

Vinyl D4: 2,4,6,8-Tetramethyl-2,4,6,8-tetravinyl-cyclotetrasiloxane (CAS No. 2554-06-5, monocyclic organosiloxane), available from The Dow Chemical Company. TAIC: Triallyl isocyanurate from Hunan Farida Technology, Co. Ltd. VMMS: 3-(Trimethoxy-silyl)propylmethacrylate, from The Dow Chemical Company. TMPTA: Trimethylolpropane triacrylate [15625-89-5 ], available from SCRC. TBEC: tert-Butyl-peroxy-2-ethylhexyl carbonate [34443-12-4], from Arkema

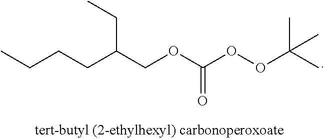 [SMILES: CCCCC(CC)COC(=O)OOC(C)(C)C]

TAEC: tert-Amylperoxy-2-ethylhexyl carbonate [70833-40-8], from Arkema,

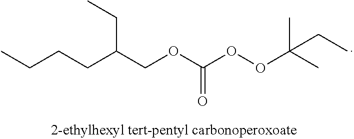 [SMILES: CCCCC(CC)COC(=O)OOC(C)(C)CC]

TRIGANOX 301: 3,6,9-Triethyl-3,6,9-trimethyl-1,4,7-triperoxonane [24748-23-0], from Akzo,

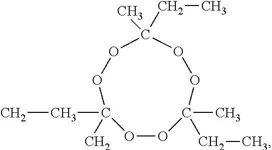 [SMILES: CCC1(C)OOC(C)(CC)OOC(C)(CC)OO1]

LUPEROX 26: tert-butyl peroxy-2-ethylhexanoate, from Arkema,

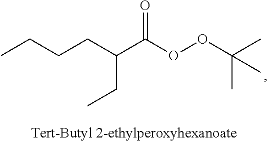

TMCH-90MO: 1,1-Di-(tert-butylperoxy)-3,3,5-trimethylcyclo-hexane [6731-36-8], 90%, from Qiangsheng Chemical,

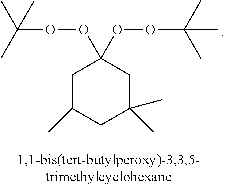 [SMILES: CC1CC(C)(C)CC(OOC(C)(C)C)(OOC(C)(C)C)C1]

CH-80MO: 1,1-Di-(tert-butylperoxy)cyclohexane [3006-86-8], 80%, from Qiangsheng Chemical,

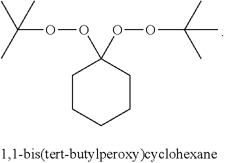 [SMILES: CC(C)(C)OOC1(OOC(C)(C)C)CCCCC1]

TABLE 1A
Ethylene-based Polymers

| | | | | Total | Vinyl/ | Vinylidene/ | Vinylene/ | Trisub/ | ENB/ |
|---|---|---|---|---|---|---|---|---|---|
| | | Density, | 12 | Unsats/ | 1000 C | 1000 C | 1000 C | 1000 C | 1000 C |
| Name | Type | g/cc | dg/min | 1000 C | (% Vinyl) | (% Vinylidene) | (% Vinylene) | (% Trisub) | (% ENB) |
| ENGAGE | EO POE | 0.870 | 30 | 0.078 | 0.046 | 0.012 | 0.014 | 0.006 | |
| 8407 | | | | | (58.97%) | (15.38%) | (17.95%) | (7.69%) | |
| ENGAGE | EO POE | 0.873 | 14 | 0.070 | 0.048 | 0.015 | 0.007 | 0 | |
| PV 8669 | | | | | (68.57%) | (21.43%) | (10.00%) | | |
| XUS 38661 | EO POE | 0.880 | 18 | 0.123 | 0.066 | 0.028 | 0.012 | 0.017 | |
| | | | | | (53.66%) | (22.76%) | (9.76%) | (13.82%) | |
| NORDEL | EPDM | 0.868 | 0.66 | 1.27 | 0.027 | 0.053 | 0.008 | 0.011 | 1.171 |
| 3720P | | | | | (2.13%) | (4.17%) | (0.63%) | (0.87%) | (92.20%) |
| NORDEL | EPDM | 0.869 | 0.71 | 1.155 | 0.074 | 0.199 | 0.003 | 0.007 | 0.872 |
| 3722P | | | | | (6.41%) | (17.23%) | (0.26%) | (0.61%) | (75.50%) |
| EO1 | EO high | 0.871 | 13.8 | 0.43 | | | | | |
| | unsaturation | | | | | | | | |
| EO2 | EO high | 0.870 | 26.7 | 0.71 | 0.46 | 0.13 | 0.09 | 0.03 | |
| | unsaturation | | | | (64.79%) | (18.31%) | (12.68%) | (4.23%) | |
| EO3 | EO high | 0.870 | 4.3 | 0.59 | 0.37 | 0.12 | 0.08 | 0.02 | |
| | unsaturation | | | | (62.71%) | (20.34%) | (13.56%) | (3.39%) | |
| EO4 | EO high | 0.87 | 15.0 | 0.56 | 0.36 | 0.10 | 0.07 | 0.03 | |
| | unsaturation | | | | (64.29%) | (17.86%) | (12.50%) | (5.36%) | |
| EO5 | EO high | 0.872 | 32.1 | 0.63 | 0.33 | 0.21 | 0.07 | 0.02 | |
| | unsaturation | | | | (52.38%) | (33.33%) | (11.11%) | (3.17%) | |
| EO6 | EO high | 0.872 | 29.8 | 0.63 | 0.33 | 0.21 | 0.07 | 0.02 | |
| | unsaturation | | | | (52.38%) | (33.33%) | (11.11%) | (3.17%) | |
| EO7 | EO high | 0.874 | 26.8 | 0.68 | 0.37 | 0.23 | 0.07 | 0.01 | |
| | unsaturation | | | | (54.41%) | (33.82%) | (10.29%) | (1.47%) | |
| EO8 | EO high | 0.872 | 29.8 | 0.745 | 0.361 | 0.29 | 0.05 | 0.044 | |
| | unsaturation | | | | (48.46%) | (38.93%) | (6.71%) | (5.91%) | |
| EO9 | EO high | 0.873 | 23.6 | 0.751 | 0.361 | 0.290 | 0.056 | 0.044 | |
| | unsaturation | | | | (48.07%) | (38.62%) | (7.46%) | (5.86%) | |

Note, the % of a particular unsaturation (%pu) = [(amt. pu/1000 C)/(amt. total unsat./1000 C)] × 100; where the %pu = %vinyl, %vinylidene, %vinylene, %trisub, or %ENB.
EO = Ethylene/octene copolymer

TABLE 1B
Ethylene-based Polymers

| | | | | Total | Vinyl/ | Vinylidene/ | Vinylene/ | Trisub/ | VCH/ |
|---|---|---|---|---|---|---|---|---|---|
| | | Density | 12 | Unsats/ | 1000 C | 1000 C | 1000 C | 1000 C | 1000 C |
| Name | Type | g/cc | dg/min | 1000 C | (% Vinyl) | (% Vinylidene) | (% Vinylene) | (% Trisub) | (% VCH) |
| EB1 | EB high | 0.874 | 26.8 | 0.633 | 0.266 | 0.310 | 0.053 | 0.004 | |
| | unsaturation | | | | (35.65%) | (48.97%) | (8.37%) | (0.63%) | |
| EB2 | EB high | 0.873 | 13.5 | 0.634 | 0.226 | 0.341 | 0.056 | 0.011 | |
| | unsaturation | | | | (35.65%) | (53.79%) | (8.83%) | (1.74%) | |
| EB3 | EB high | 0.873 | 33.0 | 0.915 | 0.606 | 0.226 | 0.067 | 0.016 | |
| | unsaturation | | | | (66.23%) | (24.70%) | (7.32%) | (1.75%) | |
| EB4 | EB high | 0.872 | 28.4 | 0.267 | 0.100 | 0.109 | 0.058 | 0 | |
| | unsaturation | | | | (37.45%) | (40.82%) | (21.72%) | | |
| EB5 | EB high | 0.873 | 26.9 | 0.706 | 0.476 | 0.176 | 0.052 | 0.002 | |
| | unsaturation | | | | (67.42%) | (24.93%) | (7.37%) | (0.28%) | |
| EB6 | EB high | 0.873 | 28.7 | 0.680 | 0.418 | 0.194 | 0.062 | 0.006 | |
| | unsaturation | | | | (61.47%) | (28.53%) | (9.12%) | (0.88%) | |
| EB7 | EB high | 0.872 | 32.1 | 0.634 | 0.226 | 0.341 | 0.056 | 0.011 | |
| | unsaturation | | | | (35.65%) | (53.79%) | (8.83%) | (1.74%) | |
| EO Tele | EO telechelic | 0.873 | 27.3 | 1.078 | 0.471 | 0.101 | 0.023 | 0.009 | 0.474 |
| 1* | A¹L¹L²A² - | | | | (43.69%) | (9.37%) | (2.13%) | (0.83%) | (43.97%) |
| | TP6 from | | | | | | | | |
| | WO2020/140058 | | | | | | | | |
| EO Mono | EO monounsaturated | 0.873 | 30.8 | 0.562 | 0.436 | 0.098 | 0.018 | 0.01 | |
| 2** | A¹L¹ | | | | (77.58%) | (17.44%) | (3.20%) | (1.78%) | |
| | MP3 from | | | | | | | | |
| | WO2020/140067 | | | | | | | | |
| EO Mono | EO | 0.871 | 33.4 | 0.596 | 0.371 | 0.158 | 0.062 | 0.005 | |
| 3** | monounsaturated | | | | (62.25%) | (26.51%) | (10.40%) | (0.84%) | |
| | A¹L¹ | | | | | | | | |
| EO Mono | EO | 0.873 | 31.6 | 0.637 | 0.388 | 0.173 | 0.065 | 0.011 | |
| 4** | monounsaturated | | | | (60.91%) | (27.16%) | (10.20%) | (1.73%) | |
| | A¹L¹ | | | | | | | | |
| EO Mono | EO | 0.868 | 1.1 | 0.294 | 0.080 | 0.061 | 0.145 | 0.008 | |
| 5** | monounsaturated | | | | (27.21%) | (20.75%) | (49.32%) | (2.72%) | |
| | A¹L¹ | | | | | | | | |
| EO Mono | EO | 0.902 | 1.1 | 0.346 | 0.221 | 0.056 | 0.068 | 0.001 | |
| 6** | monounsaturated | | | | (63.87%) | (16.18%) | (19.65%) | (0.29%) | |
| | A¹L¹ | | | | | | | | |
| EO Mono | EO | 0.876 | 18.9 | 0.386 | 0.176 | 0.022 | 0.106 | 0.082 | |
| 7** | monounsaturated | | | | (45.60%) | (5.70%) | (27.46%) | (21.24%) | |
| | A¹L¹ | | | | | | | | |

*CTA = TCHEA (Tris-(2-(cyclohex-3-en-1-yl)ethyl)aluminum.
**CTA = TEA (Triethylaluminum).
EB = Ethylene/butene copolymer
Note, the % of a particular unsaturation (%pu) = {[amt. pu/1000 C)/(amt. total unsat./1000 C)] × 100}; where the %pu = %vinyl, %vinylidene, %vinylene, %trisub, or %ENB.

TABLE 1C
Ethylene-based Polymers

| | | | | | | Mn* Total | Mn* Total | Total |
|---|---|---|---|---|---|---|---|---|
| | Mn | Mn | Mw | Mw | | Unsat/1000 C | Unsat/1000 C | Unsats/ |
| | (g/mol) | (kg/mol) | (g/mol) | (kg/mol) | MWD | (g/mol) | (kg/mol) | 1000 C |
| ENGAGE 8407 | 23100 | 23.1 | 49338 | 49.3 | 2.14 | 1802 | 1.8 | 0.078 |
| ENGAGE PV | 27071 | 27.1 | 57068 | 57.1 | 2.11 | 1895 | 1.9 | 0.07 |
| 8669 | | | | | | | | |
| XUS 38661 | 21915 | 21.9 | 50693 | 50.7 | 2.31 | 2696 | 2.7 | 0.123 |
| NORDEL 3720P | 33216 | 33.2 | 120240 | 120.2 | 3.62 | 42184 | 42.2 | 1.27 |
| NORDEL 3722P | 24414 | 24.4 | 103953 | 104.0 | 4.26 | 28198 | 28.2 | 1.155 |
| EO1 | 13516 | 13.5 | 63438 | 63.4 | 4.69 | 5812 | 5.8 | 0.43 |
| EO2 | 27470 | 27.5 | 58107 | 58.1 | 2.12 | 19504 | 19.5 | 0.71 |
| EO3 | 24213 | 24.2 | 50638 | 50.6 | 2.09 | 14286 | 14.3 | 0.59 |
| EO4 | 33315 | 33.3 | 115535 | 115.5 | 3.47 | 18656 | 18.7 | 0.56 |
| EO5 | 20300 | 20.3 | 57589 | 57.6 | 2.84 | 12789 | 12.8 | 0.63 |
| EO6 | 19804 | 19.8 | 53277 | 53.3 | 2.69 | 12477 | 12.5 | 0.63 |
| EO7 | 17554 | 17.6 | 46664 | 46.7 | 2.66 | 11937 | 11.9 | 0.68 |
| EO8 | 22267 | 22.3 | 50496 | 50.5 | 2.27 | 16589 | 16.6 | 0.745 |
| EO9 | 21822 | 21.8 | 48651 | 48.7 | 2.23 | 16388 | 16.4 | 0.751 |
| EB1 | 19885 | 19.9 | 44785 | 44.8 | 2.25 | 12587 | 12.6 | 0.633 |
| EB2 | 18653 | 18.7 | 49481 | 49.5 | 2.66 | 11826 | 11.8 | 0.634 |
| EB3 | 10491 | 10.5 | 41784 | 41.8 | 3.98 | 9599 | 9.6 | 0.915 |
| EB4 | 19468 | 19.5 | 41842 | 41.8 | 2.15 | 5198 | 5.2 | 0.267 |
| EB5 | 12519 | 12.5 | 44424 | 44.4 | 3.55 | 8838 | 8.8 | 0.706 |
| EB6 | 14370 | 14.4 | 44721 | 44.7 | 3.11 | 9772 | 9.8 | 0.68 |
| EB7 | 15714 | 15.7 | 42461 | 42.5 | 2.70 | 9963 | 10.0 | 0.634 |
| EO Tele 1 | 19168 | 19.2 | 49262 | 49.3 | 2.57 | 20663 | 20.7 | 1.078 |
| EO Mono 2 | 18823 | 18.8 | 51010 | 51.0 | 2.71 | 10579 | 10.6 | 0.562 |
| EO Mono 3 | 21332 | 21.3 | 49277 | 49.3 | 2.31 | 12714 | 12.7 | 0.596 |
| EO Mono 4 | 21174 | 21.2 | 48912 | 48.9 | 2.31 | 13488 | 13.5 | 0.637 |
| EO Mono 5 | 53722 | 53.7 | 114965 | 115.0 | 2.14 | 15794 | 15.8 | 0.294 |
| EO Mono 6 | 45508 | 45.5 | 100118 | 100.1 | 2.20 | 15746 | 15.7 | 0.346 |
| EO Mono 7 | 23950 | 24.0 | 51405 | 51.4 | 2.15 | 9245 | 9.3 | 0.386 |

### Polymer Syntheses for EO1-EO9 and EB1-EB7

### Preparation of BPP E (Ligand Disclosed in WO2018022975 A1)

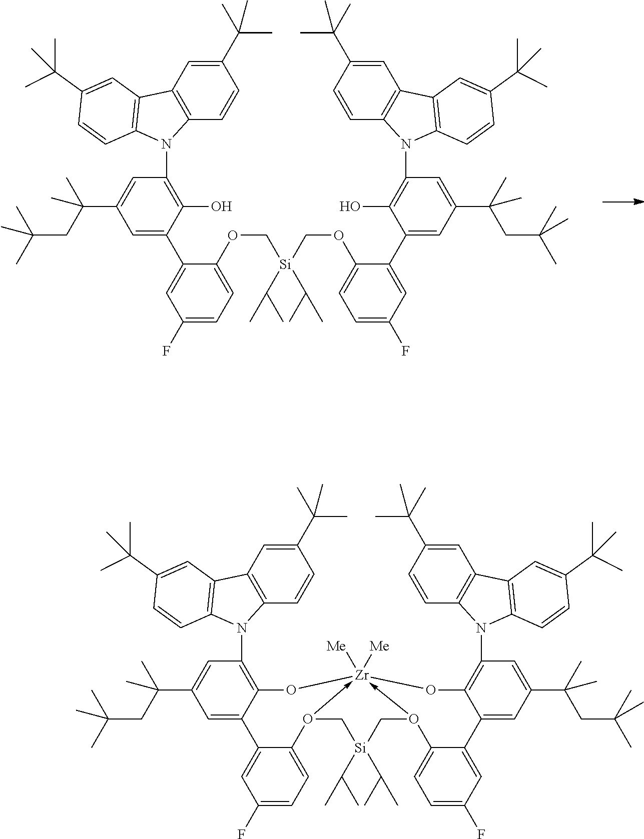

### Synthesis of 6′,6′″-(((diisopropylsilanediyl)bis(methylene))bis(oxy))bis(3-(3,6-di-tert-butyl-9H-carbazol-9-yl)-3′-fluoro-5-(2,4,4-trimethylpentan-2-yl)-[1,1′-biphenyl]-2-ol)dimethyl-zirconium (BPP-E)

The MeMgBr in diethyl ether (3.00 M, 5.33 mL, 16.0 mmol) was added to a −30° C. solution of ZrCl₄ (0.895 g, 3.84 mmol) in toluene (60 mL). After stirring for three minutes, the solid ligand (5.00 g, 3.77 mmol) was added portion-wise. The mixture was stirred for eight hours, then the solvent was removed, under reduced pressure, overnight, to afford a dark residue. Hexanes/toluene (10:1, 70 mL) was added to the residue, the solution was shaken for a few minutes, at room temperature, then this material was passed through a fritted funnel CELITE plug. The frit was extracted with hexanes (2×15 mL). The combined extracts were concentrated to dryness under reduced pressure. Pentane (20 mL) was added to the tan solid, the heterogeneous mixture was placed in the freezer (−35° C.) for 18 hours. The brown pentane layer was removed using a pipette. The remaining material was dried under vacuum, which provided BPP-E (4.50 g, yield: 83%) as a white powder.

¹H NMR (400 MHZ, C₆D₆) δ8.65-8.56; (m, 2H), 8.40; (dd, J=2.0, 0.7 Hz, 2H), 7.66-7.55; (m, 8H), 7.45; (d, J=1.9 Hz, 1H), 7.43; (d, J=1.9 Hz, 1H), 7.27; (d, J=2.5 Hz, 2H), 7.10; (d, J=3.2 Hz, 1H), 7.08; (d, J=3.1 Hz, 1H), 6.80; (ddd, J=9.0, 7.4, 3.2 Hz, 2H), 5.21; (dd, J=9.1, 4.7 Hz, 2H), 4.25; (d, J=13.9 Hz, 2H), 3.23; (d, J=14.0 Hz, 2H), 1.64-1.52; (m, 4H), 1.48; (s, 18H), 1.31; (s, 24H), 1.27; (s, 6H), 0.81; (s, 18H), 0.55; (t, J=7.3 Hz, 12H), 0.31; (hept, J=7.5 Hz, 2H), −0.84; (s, 6H); ¹⁹F NMR (376 MHZ, C₆D₆) δ−116.71.

### EO2 (Ethyleneloctene Copolymer)—Representative Polymerization

EO2 was prepared in a one gallon polymerization reactor that was hydraulically full, and operated at steady state conditions. The catalysts and cocatalysts are listed in Table 2. The solvent, hydrogen, catalysts, and cocatalysts were fed to the reactor according to the process conditions outlined in Tables 3A-3C. The solvent was ISOPAR E, supplied by the ExxonMobil Chemical Company. The reactor temperature was measured at or near the exit of the reactor. The copolymer was isolated and pelletized.

TABLE 2
Catalysts and Cocatalysts

| Catalyst (CAT) | Description |
|---|---|
| BPP-A | 6′,6″′-(propane-1,3-diylbis(oxy))bis(3-(3,6-di-tert-butyl-9H-carbazol-9-yl)-3′-fluoro-5-(2,4,4- |
| WO2012/027448 | trimethylpentan-2-yl)-[1,1′-biphenyl]-2-ol)dimethyl-zirconium |
| BPP-B | 6′,6″′-(((diisopropylsilanediyl)bis(methylene))bis(oxy))bis(3-(3,6-di-tert-butyl-9H-carbazol-9-yl)- |
| WO2018/022975 | 3′-fluoro-5-(2,4,4-trimethylpentan-2-yl)-[1,1′-biphenyl]-2-ol)dimethyl-hafnium |
| BPP-C | 6″,6″″′-(propane-1,3-diylbis(oxy))bis(3,3″,5-tri-tert-butyl-5′-methyl-[1,1′:3′,1″-terphenyl]-2′- |
| US20040010103 | ol)dimethyl-zirconium |
| WO2007/136494 | |
| BPP-D | 2′,2″′-((((1R,2R)-cyclohexane-1,2-diyl)bis(methylene))bis(oxy))bis(3-(9H-carbazol-9-yl)-5-methyl- |
| US20040010103 | [1,1′-biphenyl]-2-ol)dimethyl-zirconium |
| WO2007/136494 | |
| BPP-E | 6′,6″′-(((diisopropylsilanediyl)bis(methylene))bis(oxy))bis(3-(3,6-di-tert-butyl-9H-carbazol-9-yl)- |
| | 3′-fluoro-5-(2,4,4-trimethylpentan-2-yl)-[1,1′-biphenyl]-2-ol)dimethyl-zirconium |
| BPP-F | 6′,6″′-((2-(tert-butyl)propane-1,3-diyl)bis(oxy))bis(3-(3,6-di-tert-butyl-9H-carbazol-9-yl)-3′-fluoro- |
| WO2016/014749 | 5-(2,4,4-trimethylpentan-2-yl)-[1,1′-biphenyl]-2-ol) dimethyl-zirconium |
| Cocatalyst | |
| CoCAT 1 | A mixture of methyldi(C₁₄₋₁₈ alkyl)ammonium salts of tetrakis(pentafluorophenyl)borate, prepared |
| | by reaction of a long chain trialkylamine (Armeen ™ M2HT, available from Akzo-Nobel, Inc.), |
| | HCl and Li[B(C₆F₅)₄], substantially as disclosed in U.S. Pat. No. 5,919,983, Ex. 2 (no further purification |
| | performed) (Boulder Scientific) |
| CoCAT 2 | Modified methylalumoxane (MMAO) Type 3A (no further purification performed) (Akzo Nobel) |
| CoCAT3 | Modified methylalumoxane (MMAO)* |

*Modified with n-octyl substituents, such that the methyl:n-octyl ratio is approximately 6:1, and containing 10-20% (mol %) trialkyl aluminum species.

TABLE 3A
Reactor Conditions

| | Reactor | Comonomer | Solvent, | Ethylene, | Comonomer, | Hydrogen, | ethylene |
|---|---|---|---|---|---|---|---|
| | Temp., ° C. | Type | lb/hr | lb/hr | lb/hr | sccm | conversion, % |
| EO1 | 165 | 1-octene | 21.93 | 4.15 | 5.85 | 154.8 | 81.7 |
| EO2 | 197 | 1-octene | 41.87 | 3.67 | 8.56 | 3.2 | 75.8 |
| EO3 | 197 | 1-octene | 41.84 | 3.67 | 7.79 | 3.2 | 76.2 |
| EO4 | 190 | 1-octene | 41.87 | 3.67 | 8.81 | 3.2 | 71.1 |
| EO5 | 157 | 1-octene | 41.83 | 3.67 | 6.46 | 3.2 | 68.8 |
| EO6 | 165 | 1-octene | 41.82 | 3.67 | 6.82 | 3.2 | 70.0 |
| EO7 | 173 | 1-octene | 41.85 | 3.67 | 6.81 | 3.2 | 70.4 |
| EO8 | 195 | 1-octene | 20.70 | 3.54 | 3.84 | 20.0 | 89.1 |
| EO9 | 185 | 1-octene | 25.80 | 3.54 | 4.00 | 28.8 | 87.0 |
| EB1 | 195 | 1-butene | 24.50 | 4.20 | 3.08 | 40.0 | 84.4 |
| EB2 | 195 | 1-butene | 24.76 | 4.21 | 2.72 | 20.0 | 89.8 |
| EB3 | 195 | 1-butene | 24.01 | 4.20 | 3.23 | 54.2 | 85.4 |
| EB4 | 195 | 1-butene | 24.17 | 4.21 | 3.28 | 66.0 | 84.9 |
| EB5 | 195 | 1-butene | 24.46 | 4.21 | 3.17 | 41.6 | 84.8 |
| EB6 | 195 | 1-butene | 24.85 | 4.21 | 2.76 | 38.9 | 89.7 |
| EB7 | 195 | 1-butene | 24.68 | 4.20 | 2.72 | 31.9 | 89.8 |

TABLE 3B
Catalyst Feed Flows and Efficiency

| | | | CAT-1 | | | CAT-2 | Overall Catalyst |
|---|---|---|---|---|---|---|---|
| | | CAT-1 | Solution | | CAT-2 | Solution | Efficiency, |
| | | Solution | Metal Conc., | | Solution | Metal Conc., | (g copolymer/g total |
| | CAT-1 | Flow, lb/hr | ppm* | CAT-2 | Flow, lb/hr | ppm* | catalyst metal) |
| EO1 | BPP-B | 0.50 | 1.39 | BPP-F | 0.24 | 3.40 | 3,560,000 |
| EO2 | BPP-A | 0.42 | 2.15 | — | — | — | 5,230,000 |
| EO3 | BPP-A | 0.47 | 2.15 | BPP-B | 0.70 | 0.98 | 2,820,000 |
| EO4 | BPP-A | 0.49 | 2.15 | — | — | — | 4,280,000 |
| EO5 | BPP-A | 0.21 | 5.79 | — | — | — | 3,598,000 |
| EO6 | BPP-A | 0.20 | 5.79 | — | — | — | 3,984,000 |
| EO7 | BPP-A | 0.23 | 5.79 | — | — | — | 2,836,000 |
| EO8 | BPP-E | 0.39 | 4.98 | — | — | — | 2,744,000 |
| EO9 | BPP-E | 0.19 | 4.98 | — | — | — | 5,363,000 |
| EB1 | BPP-E | 0.19 | 4.98 | — | — | — | 5,561,000 |
| EB2 | BPP-E | 0.32 | 4.98 | — | — | — | 3,374,000 |
| EB3 | BPP-E | 0.23 | 5.32 | — | — | — | 4,307,000 |
| EB4 | BPP-C | 0.34 | 14.68 | — | — | — | 1,058,000 |
| EB5 | BPP-D | 0.14 | 6.52 | — | — | — | 5,555,000 |
| EB6 | BPP-D | 0.20 | 6.52 | — | — | — | 3,982,000 |
| EB7 | BPP-E | 0.37 | 4.98 | — | — | — | 2,874,000 |

*The “ppm” amount based on the weight of the respective catalyst feed solution.

TABLE 3C
Cocatalyst Feed Flows

| | CoCAT 1 | CoCAT 1 | CoCAT 2 | CoCAT 2 | CoCAT 3 | CoCAT 3 |
|---|---|---|---|---|---|---|
| | Solution | Solution | Solution Flow, | Solution Conc., | Solution Flow, | Solution Conc., |
| | Flow, lb/hr | Conc., ppm* | lb/hr | ppm Al** | lb/hr | ppm Al** |
| EO1 | 0.30 | 61.53 | 0.17 | 42.00 | — | — |
| EO2 | 0.46 | 30.77 | 0.39 | 34.67 | — | — |
| EO3 | 0.69 | 30.77 | 0.29 | 34.67 | — | — |
| EO4 | 0.54 | 30.77 | 0.22 | 34.67 | — | — |
| EO5 | — | — | — | — | 0.37 | 74.72 |
| EO6 | — | — | — | — | 0.35 | 74.72 |
| EO7 | — | — | — | — | 0.40 | 74.72 |
| EO8 | — | — | — | — | 0.26 | 222.68 |
| EO9 | — | — | — | — | 0.26 | 222.68 |
| EB1 | — | — | — | — | 0.29 | 222.68 |
| EB2 | — | — | — | — | 0.29 | 222.68 |
| EB3 | 0.2 | 86.9 | — | — | 0.28 | 222.68 |
| EB4 | — | — | — | — | 0.28 | 222.68 |
| EB5 | — | — | — | — | 0.28 | 222.68 |
| EB6 | — | — | — | — | 0.30 | 222.68 |
| EB7 | — | — | — | — | 0.29 | 222.68 |

*The “ppm” amount based on the weight of the co-catalyst feed solution.
**The “ppm” amount of Al based on the weight of the co-catalyst feed solution.

### EO Tele 1 and Mono 2, 3, 4, 5, 6, 7

### Synthesis of Tris(2-(Cyclohex-3-en-1-yl)Ethyl)Aluminum Chain Transfer Agent (“CTA 1”)

In a drybox, 4-vinyl-1-cyclohexene (3.2 mL, 24.6 mmol) and tri-isobutylaluminum (2.0 ml, 7.92 mmol) were added to 5 mL of decane, in a vial, equipped with a stir bar and a venting needle on the cap. This mixture was heated at 120° C. with stirring for three hours. After three hours, a sample was dissolved in benzene-d6 for ¹H NMR analysis, and another aliquot was hydrolyzed with water and analyzed by GC/MS. ¹H NMR showed all vinyl groups reacted, and the internal double bond remained. GC/MS showed a clean peak at m/z of 110, consistent to the molecular weight of ethylcyclohexene. Accordingly, ¹H NMR and GC/MS confirmed the synthesis of tris(2-(cyclohex-3-en-1-yl)ethyl)aluminum (CTA) via non-limiting Scheme 1, as shown below.

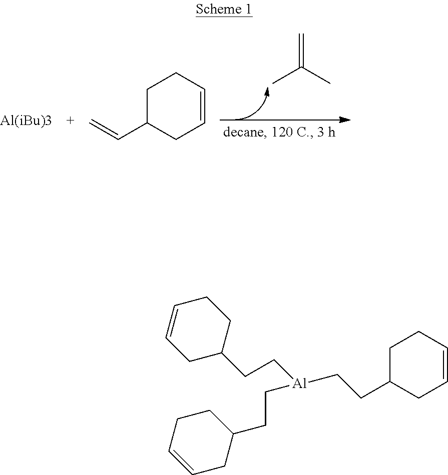

### Catalysts

CAT 1 may be prepared according to the teachings of WO 03/40195 and U.S. Pat. No. 6,953,764 B2, and has the following structure:

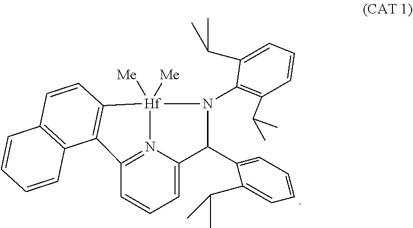

CAT 2 may by prepared according to the teachings of WO 2011/102989 A1, and has the following structure:

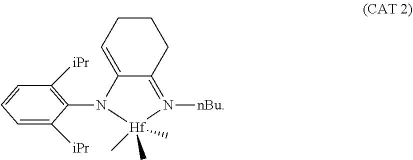

CAT 3 may be prepared according to the teachings of WO 2007/136496 A2, and has the following structure:

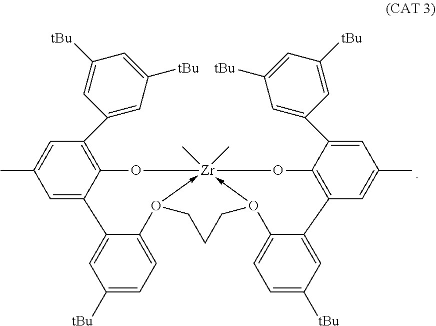

### Polymerization of EO Tele 1 (see WO2020/140058)

EO Tele 1 (A¹L¹L²A²) was made via a continuous solution polymerization as follows. The polymerization was carried out in a computer controlled autoclave reactor, equipped with an internal stirrer. Purified mixed alkanes solvent (ISOPAR E available from ExxonMobil), monomers, and molecular weight regulator (hydrogen or chain transfer agent) were supplied to a 3.8 L reactor, equipped with a jacket for temperature control. The solvent feed to the reactor was measured by a mass-flow controller. A variable speed diaphragm pump controlled the solvent flow rate and pressure to the reactor. At the discharge of the pump, a side stream was taken to provide flush flows for the procatalyst, activator, and chain transfer agent (CTA) (catalyst component solutions) injection lines. These flows were measured by mass flow meters, and controlled by control valves. The remaining solvent was combined with monomers and hydrogen, and fed to the reactor. The temperature of the solvent/monomer solution was controlled by use of a heat exchanger, before entering the reactor. This stream entered the bottom of the reactor. The catalyst component solutions were metered using pumps and mass flow meters, and were combined with the catalyst flush solvent, and introduced into the bottom of the reactor. The reactor was liquid full at “500 psig” with vigorous stirring. Polymer was removed through exit lines at the top of the reactor. All exit lines from the reactor were steam traced and insulated. The product stream was then heated at 230° C., by passing through a post reactor heater (PRH), where beta-H elimination of polymeryl-A1 took place. A small amount of isopropyl alcohol was added, along with any stabilizers or other additives, after the PRH, and before devolatilization. The polymer product was recovered by extrusion, using a devolatilizing extruder. The polymerization process conditions and results prior to the post reactor heating (PRH) are listed in Tables 4A and 4B.

Abbreviations in the tables are explained as follows: “Co.” stands for comonomer; “sccm” stands for standard cm³/min; “T” refers to temperature; “Cat” stands for Procatalyst; “CAT 1” stands for Procatalyst (CAT 1); “CoCAT-1” refers to the cocatalyst defined in Table 2; “CTA” stands for chain transfer agent”; “Poly Rate” stands for polymer production rate; “Conv” stands for percent ethylene conversion in reactor; and “Eff.” stands for efficiency, kg polymer/mg catalyst metal.

TABLE 4A
Polymerization Conditions

| | C2 | | Co. | Solv. | H2 | | | Cat. Conc. | Cat. flow |
|---|---|---|---|---|---|---|---|---|---|
| | lbs/hr | Co. Type | lbs/hr | lbs/hr | sccm | T ° C. | Cat. | ppm Hf* | lbs/hr |
| EO Tele 1 | 4.76 | 1-octene | 5.46 | 41.78 | 0 | 118 | CAT 1 | 125.5 | 0.328 |

*The “ppm” amount based on the weight of the respective feed solution.

TABLE 4B
Polymerization Conditions

| | | CTA | CTA | | CoCAT-1 | Poly. | | | |
|---|---|---|---|---|---|---|---|---|---|
| | | conc. | Flow | CoCAT-1 | Flow | Rate | Conv. | Solids | |
| | CTA | ppm Al* | lbs/hr | ppm* | lbs/hr | lbs/hr | % | % | Eff. |
| EO Tele 1 | CTA 1 | 9432 | 0.420 | 925 | 0.359 | 6.4 | 88.9 | 13.8 | 0.157 |

*The “ppm” amount based on the weight of the respective feed solution.

### Polymerization of EO Mono 2 (see WO2020/140067), EO Mono 3, 4, 5, 6, 7

Continuous solution polymerizations of EO Mono 2, 3, 4, 5, 6, 7 (A¹L¹) were carried out in similar manner as that for EO Tele 1 (see above). The polymerization conditions and results prior to post reactor heating (PHR) are listed in Tables 5A and 5B. Here “TEA” stands for triethylaluminum; “CAT 2” stands for Procatalyst (CAT 2); “CAT 3” stands for Procatalyst (CAT 3); “CoCAT-3” refers to the cocatalyst defined in Table 2; and “Armeen” refers to Armeen™ M2HT. See above “EO Tele 1 polymerization” for other abbreviations.

TABLE 5A
Polymerization Conditions

| | | | | | | | | CAT | CAT |
|---|---|---|---|---|---|---|---|---|---|
| | C2 | Co. | Co. | Solv. | H2 | T | | Conc. | flow |
| | lbs/hr | Type | lbs/hr | lbs/hr | sccm | ° C. | Cat. | ppm metal* | lbs/hr |
| EO | 3.33 | 1-octene | 3.6 | 29.3 | 0 | 115 | CAT 1 | 125.5 | 0.212 |
| Mono 2 | | | | | | | | | |
| EO | 2.85 | 1-octene | 5.6 | 36.2 | 0 | 125 | CAT 2 | 124.8 | 0.097 |
| Mono 3 | | | | | | | | | |
| EO | 3.26 | 1-octene | 4.6 | 40.4 | 0 | 125 | CAT 2 | 133.8 | 0.126 |
| Mono 4 | | | | | | | | | |
| EO | 2.90 | 1-octene | 6.2 | 36.0 | 0 | 140 | CAT 2 | 63.0 | 0.264 |
| Mono 5 | | | | | | | | | |
| EO | 3.73 | 1-octene | 2.6 | 39.5 | 0 | 140 | CAT 2 | 63.0 | 0.202 |
| Mono 6 | | | | | | | | | |
| EO | 3.21 | 1-octene | 3.1 | 24.4 | 112 | 175 | CAT 3 | 24.4 | 0.952 |
| Mono 7 | | | | | | | | | |

*The “ppm” amount based on the weight of the respective feed solution.

TABLE 5B
Polymerization Conditions

| | CTA | CTA | | CoCAT | CoCAT | Armeen | Armeen | Poly. | | | |
|---|---|---|---|---|---|---|---|---|---|---|---|
| | conc. | Flow | | Conc. | Flow | Conc. | Flow | Rate | Conv. | Solids | |
| | ppm | lbs/hr | CoCAT | ppm* | lbs/hr | ppm* | lbs/hr | lbs/hr | % | % | Eff. |
| EO | 9827 | 0.744 | CoCAT-1 | 925 | 0.232 | 0 | 0 | 4.47 | 89 | 13.7 | 0.168 |
| Mono 2 | | | | | | | | | | | |
| EO | 9820 | 0.580 | CoCAT-1 | 120 | 0.082 | 0 | 0 | 3.95 | 85 | 10.1 | 0.325 |
| Mono 3 | | | | | | | | | | | |
| EO | 9820 | 0.549 | CoCAT-1 | 129 | 0.106 | 1880 | 0.266 | 3.61 | 86 | 8.4 | 0.226 |
| Mono 4 | | | | | | | | | | | |
| EO | 4459 | 0.149 | CoCAT-1 | 1230 | 0.109 | 0 | 0 | 4.10 | 85 | 10.5 | 0.247 |
| Mono 5 | | | | | | | | | | | |
| EO | 9820 | 0.249 | CoCAT-1 | 1230 | 0.083 | 0 | 0 | 3.88 | 87 | 8.9 | 0.306 |
| Mono 6 | | | | | | | | | | | |
| EO | 8283 | 0.199 | CoCAT-3 | 665 | 0.895 | 0 | 0 | 4.23 | 88 | 15.3 | 0.182 |
| Mono 7 | | | | | | | | | | | |

CTA for EO Mono 2 through EO Mono 7 was TEA.
*The “ppm” amount based on the weight of the respective feed solution.

### Composition Preparation—Soaking

For each composition, the polymer pellets were mixed with the curing additives (peroxide, optional crosslinking coagent and optional silane coupling agent) in a fluoride HDPE bottle of 250 ml. The soaking process occurred via shaking, and an imbibition for five hours at 50° C., until no residuals were visually seen adhering to the bottle. Compositions and cure properties are shown in Tables 6 through 19.

### Results

For compositions containing a high unsaturation olefin-based polymer, replacing TBEC with alternative carbonate peroxides, like TAEC; ketal peroxides, like 1,1-di(tert-butylperoxy)-3,3,5-trimethylcyclohexane and 1,1-di(tert-butylperoxy)cyclohexane or their combinations, decreased T90, while generally increasing MH values as compared to those compositions containing a low unsaturation (<0.20/1000 C) olefin-based polymer. Note, the inventive compositions I-1 through I-6, I-41, I-42, I-45, I-46, I-50 and I-51 had exceptional cure responses with a significant decrease in T90 and increase in MH. These properties are relative to a comparative composition, similar to the respective inventive composition, except the comparative composition contains TBEC (tert-butylperoxy 2-ethylhexyl carbonate).

TABLE 6
Compositions and Cure Properties

| | C-1 | C-2 | C-3 | C-4 | C-5 |
|---|---|---|---|---|---|
| ENGAGE PV 8669 | 99.00 | 99.00 | 99.00 | 99.30 | 99.25 |
| TAEC | | 1.00 | | | |
| TBEC | 1.00 | | | | |
| LUPEROX 26A | | | 1.00 | | |
| TMCH-90MO | | | | 0.70 | |
| CH-80MO | | | | | 0.75 |
| Total (wt %) | 100.00 | 100.00 | 100.00 | 100.00 | 100.00 |
| ML@150° C., dN*m | 0.08 | 0.07 | 0.08 | 0.07 | 0.06 |
| MH@150° C., dN*m | 2.16 | 1.28 | 0.17 | 0.48 | 0.57 |
| T90@150° C., min. | 13.725 | 9.707 | n/a | n/a | n/a |
| % Δ in MH | | −40.74% | −92.13% | −77.78% | −73.61% |
| % Δ in T90 | | −16.40% | n/a | n/a | n.a |

TABLE 7
Compositions and Cure Properties

| | C-6 | C-7 | C-8 | C-9 | C-10 |
|---|---|---|---|---|---|
| ENGAGE 8407 | 99.00 | 99.00 | 99.00 | 99.30 | 99.25 |
| TAEC | | 1.00 | | | |
| TBEC | 1.00 | | | | |
| LUPEROX 26A | | | 1.00 | | |
| TMCH-90MO | | | | 0.70 | |
| CH-80MO | | | | | 0.75 |
| Total | 100.00 | 100.00 | 100.00 | 100.00 | 100.00 |
| ML@150° C., dN*m | 0.02 | 0.01 | 0.02 | 0.01 | 0.01 |
| MH@150° C., dN*m | 1.08 | 0.53 | 0.06 | 0.13 | 0.17 |
| T90@150° C., min. | 14.93 | 11.11 | n/a | n/a | n/a |
| % Δ in MH^{A} | | −50.93% | −94.44% | −87.96% | −84.26% |
| % Δ in T90^{B} | | −12.93% | n/a | n/a | n/a |

^{A}% Δ in MH = [(MH_{comp} − MH_{TBEC})/(MH_{TBEC})] × 100; where MH_{comp} is the MH value of the composition, and the MH_{TBEC} value is the MH of the comparative composition.
^{B}% Δ in T90 = [(T90_{comp} − T90_{TBEC})/(T90_{TBEC})] × 100; where T90_{comp} is the T90 value of the composition, and the T90_{TBEC} value is the T90 of the comparative composition.

TABLE 8
Compositions and Cure Properties

| | C-11 | I-1 | C-12 | I-2 | I-3 | I-4 | I-5 |
|---|---|---|---|---|---|---|---|
| EO Tele 1 | 99.00 | 99.00 | 99.00 | 99.30 | 99.25 | 98.50 | 98.50 |
| TAEC | | 1.00 | | | | 1.00 | 1.00 |
| TBEC | 1.00 | | | | | | |
| LUPEROX 26A | | | 1.00 | | | | |
| TMCH-90MO | | | | 0.70 | | | |
| CH-80MO | | | | | 0.75 | | |
| Vinyl D4 | | | | | | 0.50 | |
| TAIC | | | | | | | 0.50 |
| Total (wt %) | 100.00 | 100.00 | 100.00 | 100.00 | 100.00 | 100.00 | 100.00 |
| ML@150° C., dN*m | 0.02 | 0.01 | 0.02 | 0.01 | 0.02 | 0.02 | 0.01 |
| MH@150° C. dN*m | 1.61 | 3.62 | 0.37 | 2.6 | 2.98 | 5.49 | 6.84 |
| T90@150° C., min. | 18.44 | 13.14 | n/a | 11.18 | 12.69 | 10.47 | 10.38 |
| % Δ in MH | | 124.84% | −77.02% | 61.49% | 85.09% | 240.99% | 324.84% |
| % Δ in 90 | | −28.74% | n/a | −39.37% | −31.18% | −43.22% | −43.71% |

TABLE 9
Compositions and Cure Properties

| | C-13 | I-6 | C-14 | I-7 | I-8 | I-9 | I-10 |
|---|---|---|---|---|---|---|---|
| EO Mono 2 | 99.00 | 99.00 | 99.00 | 99.30 | 99.25 | 98.8 | 98.75 |
| TAEC | | 1.00 | | | | | |
| TBEC | 1.00 | | | | | | |
| LUPEROX 26A | | | 1.00 | | | | |
| TMCH-90MO | | | | 0.70 | | 0.70 | |
| CH-80MO | | | | | 0.75 | | 0.75 |
| TAIC | | | | | | 0.50 | 0.50 |
| Total (wt %) | 100.00 | 100.00 | 100.00 | 100.00 | 100.00 | 100.00 | 100.00 |
| ML@150° C., dN*m | 0.02 | 0.02 | 0.03 | 0.03 | 0.03 | 0.02 | 0.02 |
| MH@150° C., dN*m | 4.41 | 5.08 | 0.61 | 3.76 | 4.25 | 5.52 | 5.92 |
| T90@150° C., min. | 15.49 | 8.38 | 1.71 | 8.56 | 9.52 | 7.17 | 8.01 |
| % Δ in MH^{A} | | 15.19% | −86.17% | −14.74% | −3.63% | 25.17% | 34.24% |
| % Δ in T90^{B} | | −45.90% | −88.96% | −44.74% | −38.54% | −53.71% | −48.29% |

^{A}% Δ in MH = [(MH_{comp} − MH_{TBEC})/(MH_{TBEC})] × 100; where MH_{comp} is the MH value of the composition, and the MH_{TBEC} value is the MH of the comparative composition.
^{B}% Δ in T90 = [(T90_{comp} − T90_{TBEC})/(T90_{TBEC})] × 100; where T90_{comp} is the T90 value of the composition, and the T90_{TBEC} value is the T90 of the comparative composition.

TABLE 10
Compositions and Cure Properties

| | C-15 | C-16 | I-11 | I-12 | I-13 | I-14 |
|---|---|---|---|---|---|---|
| ENGAGE PV 8669 | 99.46 | | | | | |
| ENGAGE 8407 (30MI) | | 99.46 | | | | |
| EO4 | | | 99.46 | | | |
| EO2 | | | | 99.46 | | |
| EO Mono 2 | | | | | 99.46 | |
| EO Tele 1 | | | | | | 99.46 |
| TRIGONOX 301 | 0.54 | 0.54 | 0.54 | 0.54 | 0.54 | 0.54 |
| Total (wt %) | 100.00 | 100.00 | 100.00 | 100.00 | 100.00 | 100.00 |
| ML@200° C. dN*m | 0.00 | 0.00 | 0.01 | 0.00 | 0.00 | 0.00 |
| MH@200° C., dN*m | 0.17 | 0.04 | 1.44 | 1.12 | 2.55 | 1.25 |
| T90@200° C., min. | n/a | n/a | 8.70 | 10.07 | 10.04 | 13.82 |

TABLE 11
Compositions and Curing Data

| | C-17 | C-18 | C-19 | C-20 | C-21 | C-22 | C-23 | I-15 | C-24 | I-16 | C-25 | I-17 | C-26 | I-18 |
|---|---|---|---|---|---|---|---|---|---|---|---|---|---|---|
| ENGAGE 8407 | 99 | 99 | | | | | | | | | | | | |
| ENGAGE PV | | | 99 | 99 | | | | | | | | | | |
| 8669 | | | | | | | | | | | | | | |
| XUS 38661 | | | | | 99 | 99 | | | | | | | | |
| EO5 | | | | | | | 99 | 99 | | | | | | |
| EO6 | | | | | | | | | 99 | 99 | | | | |
| EO7 | | | | | | | | | | | 99 | 99 | | |
| EO Mono 7 | | | | | | | | | | | | | 99 | 99 |
| TBEC | 1 | | 1 | | 1 | | 1 | | 1 | | 1 | | 1 | |
| TAEC | | 1 | | 1 | | 1 | | 1 | | 1 | | 1 | | 1 |
| Total (wt %) | 100 | 100 | 100 | 100 | 100 | 100 | 100 | 100 | 100 | 100 | 100 | 100 | 100 | 100 |
| ML@150° C., | 0.02 | 0.01 | 0.08 | 0.07 | 0.07 | 0.07 | 0.08 | 0.07 | 0.06 | 0.05 | 0.02 | 0.02 | 0.05 | 0.04 |
| dN*m | | | | | | | | | | | | | | |
| MH@150° C., | 1.08 | 0.53 | 2.16 | 1.28 | 1.85 | 1.12 | 3.72 | 3.32 | 3.53 | 3.18 | 2.91 | 2.59 | 1.49 | 1.22 |
| dN*m | | | | | | | | | | | | | | |
| T90, min | 14.93 | 11.11 | 13.73 | 9.71 | 14.12 | 10.02 | 13.38 | 8.96 | 13.62 | 9.345 | 14.436 | 10.226 | 15.178 | 9.589 |
| % Δ in MH^{A} | | −50.9% | | −40.7% | | −39.5% | | −10.8% | | −9.9% | | −11.0% | | −18.1% |
| % Δ in T90^{B} | | −25.6% | | −29.3% | | −29.1% | | −33.0% | | −31.4% | | −29.2% | | −36.8% |

^{A}% Δ in MH = [(MH_{comp} − MH_{TBEC})/(MH_{TBEC})] × 100; where MH_{comp} is the MH value of the composition, and the MH_{TBEC} value is the MH of the comparative composition.
^{B}% Δ in T90 = [(T90_{comp} − T90_{TBEC})/(T90_{TBEC})] × 100; where T90_{comp} is the T90 value of the composition, and the T90_{TBEC} value is the T90 of the comparative composition.

TABLE 12
Compositions and Curing Data

| | C-27 | I-19 | C-28 | I-20 | C-29 | I-21 | C-30 | I-22 | C-31 | I-23 |
|---|---|---|---|---|---|---|---|---|---|---|
| EO8 | 99 | 99 | | | | | | | | |
| EO9 | | | 99 | 99 | | | | | | |
| EB1 | | | | | 99 | 99 | | | | |
| EB2 | | | | | | | 99 | 99 | | |
| EB3 | | | | | | | | | 99 | 99 |
| TBEC | 1 | | 1 | | 1 | | 1 | | 1 | |
| TAEC | | 1 | | 1 | | 1 | | 1 | | 1 |
| Total (wt %) | 100 | 100 | 100 | 100 | 100 | 100 | 100 | 100 | 100 | 100 |
| ML@150° C., dN*m | 0.02 | 0 | 0 | 0 | 0 | 0 | 0.06 | 0.05 | 0.03 | 0 |
| MH@150° C., dN*m | 2.14 | 1.79 | 1.89 | 1.35 | 2.24 | 1.94 | 2.87 | 2.73 | 1.23 | 0.88 |
| T90, min | 14.35 | 10.23 | 14.31 | 10.38 | 15.09 | 10.92 | 14.24 | 10.42 | 15.50 | 11.43 |
| % Δ in MH | | −16.4% | | −28.6% | | −13.4% | | −4.9% | | −28.5% |
| % Δ in T90 | | −28.7% | | −27.5% | | −27.7% | | −26.9% | | −26.2% |

TABLE 13
Compositions and Curing Data

| | C-32 | I-24 | C-33 | I-25 | C-34 | I-26 | C-35 | I-27 |
|---|---|---|---|---|---|---|---|---|
| EB4 | 99 | 99 | | | | | | |
| EB5 | | | 99 | 99 | | | | |
| EB6 | | | | | 99 | 99 | | |
| EB7 | | | | | | | 99 | 99 |
| TBEC | 1 | | 1 | | 1 | | 1 | |
| TAEC | | 1 | | 1 | | 1 | | 1 |
| Total (wt %) | 100 | 100 | 100 | 100 | 100 | 100 | 100 | 100 |
| ML@150° C., dN*m | 0 | 0 | 0.06 | 0 | 0.03 | 0 | 0.04 | 0.04 |
| MH@150° C., dN*m | 1.63 | 1.07 | 1.55 | 1.12 | 1.40 | 1.02 | 1.84 | 1.50 |
| T90, min. | 15.05 | 11.12 | 15.56 | 10.99 | 15.46 | 11.42 | 14.92 | 11.12 |
| % Δ in MH | | −34.4% | | −27.7% | | −27.1% | | −18.5% |
| % Δ in T90 | | −26.1% | | −29.4% | | −26.1% | | −25.5% |

TABLE 14
Compositions and Cure Properties

| | C-36 | I-28 | C-37 | I-29 | I-30 | C-38 | I-31 | C-39 | I-32 |
|---|---|---|---|---|---|---|---|---|---|
| NORDEL 3720 | 99.00 | 99.00 | | | | | | | |
| NORDEL 3722 | | | 99.00 | 99.30 | 99.25 | | | | |
| EO3 | | | | | | 99.00 | 99.00 | | |
| EO5 | | | | | | | | 99.00 | 99.00 |
| TAEC | | 1.00 | | | | | 1.00 | | 1.00 |
| TBEC | 1.00 | | 1.00 | | | 1.00 | | 1.00 | |
| TMCH-90MO | | | | 0.70 | | | | | |
| CH-80MO | | | | | 0.75 | | | | |
| Total (wt %) | 100.00 | 100.00 | 100.00 | 100.00 | 100.00 | 100.00 | 100.00 | 100.00 | 100.00 |
| ML@150° C., dN*m | 0.74 | 0.74 | 0.67 | 0.67 | 0.67 | 0.21 | 0.21 | 0.08 | 0.07 |
| MH@150° C., dN*m | 7.12 | 6.05 | 5.94 | 3.7 | 4.01 | 5.1 | 4.84 | 3.72 | 3.32 |
| T90@150° C., min. | 12.60 | 9.48 | 13.12 | 9.02 | 10.41 | 12.25 | 7.79 | 13.38 | 8.97 |
| % Δ in MH | | −15.03% | | −37.71% | −32.49% | | −5.10% | | −10.75% |
| % Δ in T90 | | −24.76% | | −31.25% | −20.66% | | −36.41% | | −32.96% |

TABLE 15
Compositions and Cure Properties

| | C-40 | I-33 | C-41 | I-34 | C-42 | I-35 | C-43 | I-36 | C-44 | I-37 |
|---|---|---|---|---|---|---|---|---|---|---|
| EO6 | 99.00 | 99.00 | | | | | | | | |
| EO7 | | | 99.00 | 99.00 | | | | | | |
| EO2 | | | | | 99.00 | 99.00 | | | | |
| EO4 | | | | | | | 99.00 | 99.00 | | |
| EO1 | | | | | | | | | 99.00 | 99.00 |
| TAEC | | 1.00 | | 1.00 | | 1.00 | | 1.00 | | 1.00 |
| TBEC | 1.00 | | 1.00 | | 1.00 | | 1.00 | | 1.00 | |
| Total (wt %) | 100.00 | 100.00 | 100.00 | 100.00 | 100.00 | 100.00 | 100.00 | 100.00 | 100.00 | 100.00 |
| ML@150° C., dN*m | 0.06 | 0.05 | 0.02 | 0.02 | 0.03 | 0.03 | 0.07 | 0.06 | 0.1 | 0.1 |
| MH@150° C., dN*m | 3.53 | 3.18 | 2.91 | 2.59 | 3.95 | 3.77 | 5.63 | 4.71 | 1.27 | 0.91 |
| T90@150° C., min. | 13.62 | 9.35 | 14.44 | 10.23 | 13.29 | 8.88 | 12.12 | 7.92 | 14.06 | 9.96 |
| % Δ in MH | | −9.92% | | −11.00% | | −4.56% | | −16.34% | | −28.35% |
| % Δ in T90 | | −31.35% | | −29.16% | | −33.18% | | −34.65% | | −29.16% |

TABLE 16
Compositions and Cure Properties

| | C-45 | I-38 | C-46 | C-47 | C-48 | C-49 | C-50 | C-51 | C-52 | I-39 |
|---|---|---|---|---|---|---|---|---|---|---|
| EVA E282PV | | | 98.25 | 98.25 | | | | | | |
| ENGAGE PV 8669 | | | | | 98.25 | 98.25 | | | | |
| ENGAGE 8407 | | | | | | | 98.25 | 98.25 | | |
| NORDEL 3720P | 98.25 | 98.25 | | | | | | | | |
| EO2 | | | | | | | | | 98.25 | 98.25 |
| TAEC | | 1.00 | | 1.00 | | 1.00 | | 1.00 | | 1.00 |
| TBEC | 1.00 | | 1.00 | | 1.00 | | 1.00 | | 1.00 | |
| TAIC | 0.50 | 0.50 | 0.50 | 0.50 | 0.50 | 0.50 | 0.50 | 0.50 | 0.50 | 0.50 |
| VMMS | 0.25 | 0.25 | 0.25 | 0.25 | 0.25 | 0.25 | 0.25 | 0.25 | 0.25 | 0.25 |
| Total (wt %) | 100.00 | 100.00 | 100.00 | 100.00 | 100.00 | 100.00 | 100.00 | 100.00 | 100.00 | 100.00 |
| ML@150° C., dN*m | 0.74 | 0.71 | 0.06 | 0.06 | 0.07 | 0.06 | 0.02 | 0.01 | 0.03 | 0.03 |
| MH@150° C., dN*m | 9.15 | 8.04 | 5.51 | 4.27 | 4.12 | 3.14 | 2.87 | 1.89 | 5.19 | 4.94 |
| T90@150° C., min. | 11.85 | 8.51 | 8.60 | 4.98 | 11.23 | 6.89 | 11.64 | 7.84 | 13.42 | 9.10 |
| % Δ in MH | | −12.13% | | −22.50% | | −23.79% | | −34.15% | | −4.82% |
| % Δ in T90 | | −28.19% | | −42.09% | | −38.65% | | −32.65% | | −32.19% |

TABLE 17
Compositions and Cure Properties

| | C-53 | I-40 | C-54 | I-41 | C-55 | I-42 | C-56 | I-43 | C-57 | I-44 |
|---|---|---|---|---|---|---|---|---|---|---|
| EO Tele 1 | | | 98.25 | 98.25 | | | | | | |
| EO Mono 2 | | | | | 98.25 | 98.25 | | | | |
| EO4 | 98.25 | 98.25 | | | | | | | | |
| EO3 | | | | | | | 98.25 | 98.25 | | |
| EO1 | | | | | | | | | 98.25 | 98.25 |
| TAEC | | 1.00 | | 1.00 | | 1.00 | | 1.00 | | 1.00 |
| TBEC | 1.00 | | 1.00 | | 1.00 | | 1.00 | | 1.00 | |
| TAIC | 0.50 | 0.50 | 0.50 | 0.50 | 0.50 | 0.50 | 0.50 | 0.50 | 0.50 | 0.50 |
| VMMS | 0.25 | 0.25 | 0.25 | 0.25 | 0.25 | 0.25 | 0.25 | 0.25 | 0.25 | 0.25 |
| Total (wt %) | 100.00 | 100.00 | 100.00 | 100.00 | 100.00 | 100.00 | 100.00 | 100.00 | 100.00 | 100.00 |
| ML@150° C., dN*m | 0.06 | 0.06 | 0.01 | 0.01 | 0.02 | 0.02 | 0.19 | 0.2 | 0.1 | 0.09 |
| MH@150° C., dN*m | 6.54 | 6.00 | 5.48 | 6.59 | 6.91 | 7.08 | 5.52 | 5.32 | 2.4 | 1.98 |
| T90@150° C., min. | 10.98 | 8.25 | 15.18 | 10.99 | 12.93 | 7.81 | 13.58 | 8.99 | 13.33 | 8.66 |
| % Δ in MH | | −8.26% | | 20.26% | | 2.46% | | −3.62% | | −17.50% |
| % Δ in T90 | | −24.86% | | −27.60% | | −39.60% | | −33.80% | | −35.03% |

TABLE 18
Compositions and Cure Properties

| | C-58 | I-45 | C-59 | I-46 | C-60 | I-47 | C-61 | I-48 | C-62 | I-49 | C-63 |
|---|---|---|---|---|---|---|---|---|---|---|---|
| EO Mono 3 | 99 | 99 | | | | | | | | | 98.5 |
| EO Mono 4 | | | 99 | 99 | | | | | | | |
| EO Mono 5 | | | | | 99 | 99 | | | | | |
| EO Mono 6 | | | | | | | 99 | 99 | | | |
| EO Mono 7 | | | | | | | | | 99 | 99 | |
| TAEC | | 1 | | 1 | | 1 | | 1 | | 1 | |
| TBEC | 1 | | 1 | | 1 | | 1 | | 1 | | 1 |
| TAIC | | | | | | | | | | | 0.5 |
| Vinyl D4 | | | | | | | | | | | |
| TMPTA | | | | | | | | | | | |
| VMMS | | | | | | | | | | | |
| Total | 100 | 100 | 100 | 100 | 100 | 100 | 100 | 100 | 100 | 100 | 100 |
| ML@150° C., | 0.00 | 0.01 | 0.00 | 0.01 | | 0.74 | 0.61 | 0.62 | 0.05 | 0.04 | 0.01 |
| dN*m | | | | | | | | | | | |
| MH@150° C., | 1.86 | 2.56 | 1.55 | 2.45 | | 6.89 | 13.79 | 12.73 | 1.49 | 1.22 | 3.85 |
| dN*m | | | | | | | | | | | |
| T90, min | 17.74 | 13.26 | 18.70 | 12.96 | | 7.03 | 8.52 | 4.76 | 15.18 | 9.59 | 22.55 |
| % Δ in MH | | 37.6% | | 58.1% | | | | −7.69 | | −18.1 | |
| % Δ in T90 | | −25.2% | | −30.7% | | | | −44.13 | | −36.8 | |

| | I-50 | C-64 | I-51 | C-65 | I-52 | I-53 | I-54 | I-55 | I-56 |
|---|---|---|---|---|---|---|---|---|---|
| EO Mono 3 | 98.5 | 98.5 | 98.5 | 98.5 | 98.5 | 98.75 | | 98.75 | |
| EO Mono 4 | | | | | | | 98.75 | | 98.75 |
| EO Mono 5 | | | | | | | | | |
| EO Mono 6 | | | | | | | | | |
| EO Mono 7 | | | | | | | | | |
| TAEC | 1 | | 1 | | 1 | 1 | 1 | 1 | 1 |
| TBEC | | 1 | | 1 | | | | | |
| TAIC | 0.5 | | | | | 0.5 | 0.5 | | |
| Vinyl D4 | | 0.5 | 0.5 | | | | | | |
| TMPTA | | | | 0.5 | 0.5 | | | | |
| VMMS | | | | | | 0.25 | 0.25 | 0.25 | 0.25 |
| Total | 100 | 100 | 100 | 100 | 100 | 100 | 100 | 100 | 100 |
| ML@150° C., | 0.01 | 0.01 | 0.01 | 0.02 | 0.02 | 0.02 | 0.01 | 0.01 | 0.01 |
| dN*m | | | | | | | | | |
| MH@150° C., | 5.13 | 3.55 | 4.52 | 4.44 | 4.19 | 5.56 | 5.36 | 3.93 | 3.82 |
| dN*m | | | | | | | | | |
| T90, min | 8.65 | 19.28 | 8.96 | 14.23 | 8.38 | 8.32 | 8.33 | 9.56 | 9.82 |
| % Δ in MH | 33.2% | | 27.3% | | −5.6% | | | | |
| % Δ in T90 | −61.6% | | −53.5% | | −41.1% | | | | |

TABLE 19
Compositions and Cure Properties

| | C-66 | C-67 | C-68 | C-69 | C-70 | C-71 | C-72 | I-57 |
|---|---|---|---|---|---|---|---|---|
| ENGAGE 8407 | 98.18 | | | 98.25 | | 98.25 | | |
| ENGAGE PV 8669 | | | | | 98.25 | | 98.25 | |
| EO Mono 2 | | 98.18 | | | | | | 98.4 |
| EO Tele 1 | | | 98.18 | | | | | |
| EO2 | | | | | | | | |
| EO4 | | | | | | | | |
| TBEC | 1 | 1 | 1 | 1 | 1 | | | |
| TAEC | | | | | | 1 | 1 | 0.6 |
| TMCH-90MO | | | | | | | | |
| TAIC | 0.5 | 0.5 | 0.5 | 0.5 | 0.5 | 0.5 | 0.5 | 0.75 |
| VMMS | 0.25 | 0.25 | 0.25 | 0.25 | 0.25 | 0.25 | 0.25 | 0.25 |
| T770 | 0.07 | 0.07 | 0.07 | | | | | |
| Total (wt %) | 100 | 100 | 100 | 100 | 100 | 100 | 100 | 100 |
| ML@150° C., dN*m | 0.01 | 0.02 | 0.01 | 0.02 | 0.07 | 0.01 | 0.06 | 0.02 |
| MH@150° C., dN*m | 2.90 | 7.18 | 5.52 | 2.87 | 4.09 | 1.79 | 3.14 | 6.05 |
| T90@150° C., min. | 12.36 | 12.81 | 15.34 | 11.64 | 10.98 | 7.18 | 6.89 | 9.77 |
| Gel Content, 4 + 4, wt % | | | | | | | | 7.6 |
| Gel Content, 4 + 6, wt % | | | | | | | | 80.0 |
| Gel Content, 4 + 8, wt % | 0.6 | 0.5 | 0.5 | | | | | 84.9 |
| Gel Content, 4 + 10, wt % | 23.5 | 59.1 | 17.8 | | | | | |
| Gel Content, 4 + 12, wt % | 69.6 | 74.8 | 68.2 | | | | | |
| | I-58 | I-59 | I-60 | I-61 | I-62 | I-63 | I-64 | I-65 |
| ENGAGE 8407 | | | | | | | | |
| ENGAGE PV 8669 | | | | | | | | |
| EO Mono 2 | 98.4 | 98.25 | | | 98.4 | | 98.75 | |
| EO Tele 1 | | | | | | | | |
| EO2 | | | 98.25 | | | 98.4 | | 98.4 |
| EO4 | | | | 98.25 | | | | |
| TBEC | | | | | | | | |
| TAEC | | 1 | 1 | 1 | 0.85 | 0.85 | 1 | 1.35 |
| TMCH-90MO | 0.6 | | | | | | | |
| TAIC | 0.75 | 0.5 | 0.5 | 0.5 | 0.5 | 0.5 | | |
| VMMS | 0.25 | 0.25 | 0.25 | 0.25 | 0.25 | 0.25 | 0.25 | 0.25 |
| T770 | | | | | | | | |
| Total (wt %) | 100 | 100 | 100 | 100 | 100 | 100 | 100 | 100 |
| ML@150° C., dN*m | 0.02 | 0.02 | 0.02 | 0.05 | 0.02 | 0.02 | 0.01 | 0.03 |
| MH@150° C., dN*m | 5.00 | 7.08 | 5.36 | 6.11 | 6.66 | 4.87 | 5.39 | 4.42 |
| T90@150° C., min. | 9.96 | 7.81 | 8.30 | 7.50 | 8.46 | 8.98 | 8.95 | 8.80 |
| Gel Content, 4 + 4, wt % | 22.5 | 66.8 | 1.2 | 6.4 | 19.3 | 2.0 | 1.4 | 1.4 |
| Gel Content, 4 + 6, wt % | 77.5 | 89.4 | 83.2 | 88.7 | 82.0 | 84.4 | 82.0 | 75.2 |
| Gel Content, 4 + 8, wt % | 81.8 | 92.8 | 89.7 | 92.4 | 89.3 | 87.5 | 87.9 | 86.7 |
| Gel Content, 4 + 10, wt % | | | | | | | | |
| Gel Content, 4 + 12, wt % | | | | | | | | |

1. A process to form a crosslinked composition, the process comprising applying heat, and optionally radiation, to a composition that comprises at least the following components a) and b):
a) an olefin-based polymer that comprises a total unsaturation ≥0.20/1000 C;
b) at least one peroxide selected from at least one of the following:
i) a peroxide comprising at least one peroxy group comprising an oxyl radical unit selected from Radical I, or
ii) a peroxide comprising at least one peroxy group comprising an oxyl radical unit selected from Radical II, or
iii) a peroxide comprising at least one peroxy group comprising an oxyl radical unit selected from Radical III, or
iv) a peroxide comprising at least one peroxy group comprising an oxyl radical unit selected from Radical IV, or
v) any combination of i) through iv); and
wherein Radical I, Radical II, Radical III or Radical IV are each shown below: 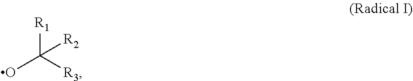
wherein R1, R2 and R3 are each independently selected from H, CH₃, CH₂-Alkyl, or Aryl; and each of R1, R2 and R3 may be the same or different from one or both of the other two; and at least one of R1, R2 or R3 is CH₂-Alkyl; 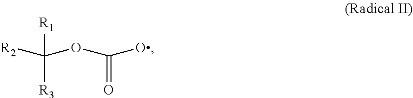
wherein R1, R2 and R3 are each independently selected from H, CH₃, CH₂-Alkyl or Aryl; and each of R1, R2 and R3 may the same or different from one or both of the other two; and at least one of R1, R2 or R3 is CH₂-Alkyl; 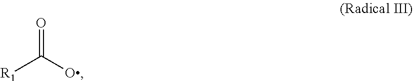
wherein R1 is CH2-Alkyl; 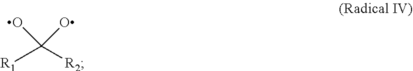
wherein R1 and R2 are selected from the following y) or z):
y) R1 and R2 are each independently CH₃, or CH₂-Alkyl; and R1 and R2 may be the same or different; and at least one of R1 or R2 is CH₂-Alkyl; or
z) R1 and R2 are bonded together to form an aliphatic ring; and wherein the ring comprises at least one —CH₂— structure adjacent to the quaternary carbon (R1—C(O·)(O·)—R2).

2. The process of claim 1, wherein component b is a peroxide comprising at least one peroxy group comprising an oxyl radical unit selected from Radical I.

3. The process of claim 1, wherein component b is a peroxide comprising at least one peroxy group comprising an oxyl radical unit selected from Radical II.

4. The process of claim 1, wherein component b is a peroxide comprising at least one peroxy group comprising an oxyl radical unit selected from Radical III.

5. The process of claim 1, wherein component b is a peroxide comprising at least one peroxy group comprising an oxyl radical unit selected from Radical IV.

6. The process of claim 1, wherein component a is an ethylene-based polymer.

7. The process of claim 1, wherein component a is selected from a telechelic polyolefin of the formula A¹L¹L²A², an unsaturated polyolefin of the formula A¹L¹, an ethylene/alpha-olefin/nonconjugated polyene interpolymer, or an ethylene/alpha-olefin interpolymer.

8. A crosslinked composition formed by the process of claim 1.

9. A composition that comprises at least the following components a) and b):
a) an olefin-based polymer that comprises a total unsaturation ≥0.20/1000 C;
b) at least one peroxide selected from at least one of the following:
i) a peroxide comprising at least one peroxy group comprising an oxyl radical unit selected from Radical I, or
ii) a peroxide comprising at least one peroxy group comprising an oxyl radical unit selected from Radical II, or
iii) a peroxide comprising at least one peroxy group comprising an oxyl radical unit selected from Radical III, or
iv) a peroxide comprising at least one peroxy group comprising an oxyl radical unit selected from Radical IV, or
v) any combination of i) through iv); and
wherein Radical I, Radical II, Radical III or Radical IV are each shown below: 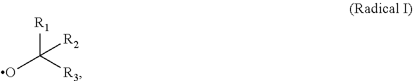
wherein R1, R2 and R3 are each independently selected from H, CH₃, CH₂-Alkyl, or Aryl; and each of R1, R2 and R3 may be the same or different from one or both of the other two; and at least one of R1, R2 or R3 is CH₂-Alkyl; 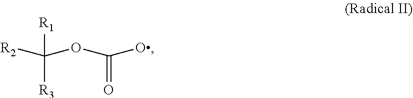
wherein R1, R2 and R3 are each independently selected from H, CH₃, CH₂-Alkyl or Aryl; and each of R1, R2 and R3 may the same or different from one or both of the other two; and at least one of R1, R2 or R3 is CH₂-Alkyl; 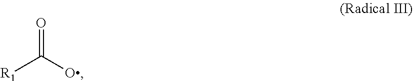
wherein R1 is CH₂-Alkyl; 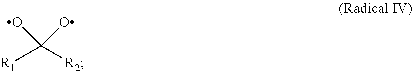
wherein R1 and R2 are selected from the following y) or z):
y) R1 and R2 are each independently CH₃, or CH₂-Alkyl; and R1 and R2 may be the same or different; and at least one of R1 or R2 is CH₂-Alkyl; or
z) R1 and R2 are bonded together to form an aliphatic ring; and wherein the ring comprises at least one —CH₂— structure adjacent to the quaternary carbon (R1—C(O·)(O·)—R2).

10. The composition of claim 9, wherein component b is a peroxide comprising at least one peroxy group comprising an oxyl radical unit selected from Radical I.

11. The composition of claim 9, wherein component b is a peroxide comprising at least one peroxy group comprising an oxyl radical unit selected from Radical II.

12. The composition of claim 9, wherein component b is a peroxide comprising at least one peroxy group comprising an oxyl radical unit selected from Radical III.

13. The composition of claim 9, wherein component b is a peroxide comprising at least one peroxy group comprising an oxyl radical unit selected from Radical IV.

14. The composition of claim 9, wherein component a is an ethylene-based polymer.

15. The composition of claim 9, wherein component a is selected from a telechelic polyolefin of the formula A¹L¹L²A², an unsaturated polyolefin of the formula A¹L¹, an ethylene/alpha-olefin/nonconjugated polyene interpolymer, or an ethylene/alpha-olefin interpolymer.

16. The composition of claim 9, wherein component a has a molecular weight distribution MWD (=Mw/Mn) from 1.80 to 5.00.

17. The composition of claim 9, wherein the composition comprises from 50.0 wt % to 100.0 wt % of the sum of components a and b, based on the weight of the composition.

18. The composition of claim 9, wherein the composition has a percent change (Δ) in T90 from −80% to −10%, as compared to a comparative composition, similar to the composition, except the comparative composition contains TBEC (tert-butylperoxy-2-ethylhexyl carbonate) as the peroxide; and wherein the % Δ in T90=[(T90_{comp}−T90_{TBEC})/(T90_{TBEC})]×100; where T90_{comp} is the T90 value of the composition, and the T90_{TBEC} value is the T90 of the comparative composition.

19. The composition of claim 9, wherein the composition has a percent change (A) in MH from −40% to 400%, as compared to a comparative composition, similar to the composition, except the comparative composition contains TBEC (tert-butylperoxy-2-ethylhexyl carbonate) as the peroxide; and wherein the % Δ in MH=[(MH_{comp}−MH_{TBEC})/(MH_{TBEC})]×100; where MH_{comp} is the MH value of the composition, and the MH_{TBEC} value is the MH of the comparative composition.

20. An article comprising at least one component formed from the composition of claim 8.
